(19) United States
(12) Patent Application Publication
(10) Pub. No.: US 2010/0091293 A1
(43) Pub. Date: Apr. 15, 2010

(54) SEMITRANSPARENT INTEGRATED OPTIC MIRROR

(75) Inventor: Yosi Shani, Maccabim (IL)

Correspondence Address: MARTIN D. MOYNIHAN d/b/a PRTSI, INC., P.O. BOX 16446, ARLINGTON, VA, 22215, US

(73) Assignee: OMS Displays Ltd., Jerusalem (IL)

(21) Appl. No.: 12/445,316

(22) PCT Filed: Oct. 14, 2007
(86) PCT No.: PCT/IL07/01228

§ 371 Date: Dec. 9, 2009

Related U.S. Application Data
(60) Provisional application No. 60/852,130, filed on Oct. 17, 2006.
(60) Provisional application No. 60/874,480, filed on Dec. 13, 2006.

(51) Int. Cl. G01B 9/02; G02B 6/26; H01S 5/026; H01L 33/00; B05D 5/06

(52) U.S. Cl. 356/477; 385/29; 385/31; 372/45.01; 257/98; 427/162; 257/E33.067

(57) ABSTRACT

An optical device is disclosed. The device comprises a waveguide formed within a substrate; and at least one semitransparent mirror structure formed within the waveguide and being designed and constructed to partially reflect light propagating in the waveguide such that a portion of the light is emitted through the surface of the waveguide. The semitransparent mirror structure(s) is capable of reflecting light while substantially preserving the shape of the light profile in the waveguide.

### FIELD AND BACKGROUND OF THE INVENTION

The present invention relates to optics and, more particularly, to an optical device and a method for manufacturing an optical device.

Optical fibers and optical waveguides are devices which transmit light therein. Systems incorporating optical waveguides are well known and find an ever-increasing variety of applications, including optical fiber communications systems, medical instruments, copiers, printers, facsimile machines, display device and lighting.

In many of the applications employing optical waveguides, small amounts of light traversing the waveguide need to be tapped from the waveguide, e.g., for monitoring purposes or for light splitting.

In the field of optical fibers and waveguides, tapping is traditionally achieved via coupling power to modes that radiate out of the waveguide. Means of coupling to radiation modes are perturbations in the structure of the waveguides (e.g. strong bends) or perturbations inside the waveguide (e.g. wedge which partially occupies the waveguide core's cross section) Another technique is the optical coupler which includes the use of two separate optical waveguides positioned within an intermediate medium and arranged relatively close and substantially parallel to each other. Light propagating in a first direction in one optical waveguide is partially or fully transferred to the other optical waveguide by the existence of a weak coupling between the two waveguides through the intermediate medium.

Embedded waveguides and methods of tapping light are described in, e.g., International Publication Nos. WO2006/064500 and WO2007/046100 assigned to the same assignee as the present application. There, light tapping is typically achieved by a total internal reflection mirror or a perturbation, such as a wedge or the like, which partially occupies the waveguide core's cross section. Another technique employs Bragg reflectors and semi-transparent mirrors.

### SUMMARY OF THE INVENTION

According to one aspect of the present invention there is provided an optical device. The device comprises: a waveguide formed within a substrate and having a surface and at least one end; and at least one semitransparent mirror structure formed within the waveguide and being designed and constructed to partially reflect light propagating in the waveguide such that a portion of the light is emitted through the surface.

According to further features in preferred embodiments of the invention described below, the semitransparent mirror(s) is capable of reflecting at least two modes of the light with substantially equal reflection efficiencies.

According to still further features in the described preferred embodiments the semitransparent mirror(s) being capable of reflecting at least one optical mode with substantially no power transfer to other modes.

According to still further features in the described preferred embodiments the substrate comprises at least one reflective layer.

According to still further features in the described preferred embodiments the semitransparent mirror(s) is designed and constructed to partially reflect both light propagating from one end of the waveguide and light propagating from another end of the waveguide.

According to yet another aspect of the present invention there is provided an interferometer device. The device comprises a waveguide, an edge mirror terminating a first end of the waveguide, a surface mirror positioned opposite to a first surface of the waveguide, and at least one semitransparent mirror structure formed within the waveguide.

According to further features in preferred embodiments of the invention described below, the semitransparent mirror structure(s) is designed and constructed such that light entering the waveguide through a second end of the waveguide is partially reflected in the direction of the surface mirror and partially transmitted in the direction of the edge mirror; and light reflected by the surface mirror or the edge mirror is at least partially coupled out of a second surface of the waveguide by the semitransparent mirror(s) structure.

According to still another aspect of the present invention there is provided a surface emitting laser device. The device comprises: a waveguide formed in a substrate and having a first end terminated by a first edge mirror and a second end terminated by a second edge mirror; a laser pump for inducing light within the waveguide; and at least one semitransparent mirror structure formed within the waveguide.

According to further features in preferred embodiments of the invention described below, the semitransparent mirror structure(s) is designed and constructed such that the light passes a plurality of times between the first and the second edge mirrors and being at least partially coupled out of a surface of the waveguide by the semitransparent mirror(s) structure.

According to an additional aspect of the present invention there is provided a light emitting device. The device comprises a waveguide having therein an active layer for generating light, and at least one semitransparent mirror structure formed within the active layer.

According to further features in preferred embodiments of the invention described below, the semitransparent mirror structure(s) is designed and constructed such that light generated by the active layer is at least partially coupled out of a surface of the waveguide by the semitransparent mirror(s) structure.

According to still further features in the described preferred embodiments the semitransparent mirror(s) comprises a first film characterized by a first refractive index n₁, and a second film characterized by a second refractive index n₂ being different from the first refractive index.

According to still further features in the described preferred embodiments the semitransparent mirror(s) comprises a first facet slanted with respect to the waveguide at a first angle, and a second facet slanted with respect to the waveguide at a second angle being different from the first angle.

According to still further features in the described preferred embodiments the waveguide comprises a core characterized by a refractive index which is approximately the arithmetic mean of the n₁ and the n₂.

According to still further features in the described preferred embodiments the semitransparent mirror(s) comprises a first film oriented at a first orientation with respect to the waveguide, and a second film oriented at a second orientation with respect to the waveguide, the first orientation being different from the second orientation.

According to still further features in the described preferred embodiments the first film and the second film are characterized by generally identical refractive indices.

According to still further features in the described preferred embodiments the first orientation and the second orientation form a V-shape structure, and wherein the substrate comprises at least one reflective layer

According to still further features in the described preferred embodiments the semitransparent mirror(s) is characterized by a refractive index gradient along a propagation direction of the light within the waveguide.

According to still further features in the described preferred embodiments a thickness of the semitransparent mirror is selected so as to minimize distortions of all propagation modes in the waveguide.

According to still further features in the described preferred embodiments the waveguide comprises a core characterized by a cross section area and the semitransparent mirror(s) occupies the cross section area by its entirety.

According to still further features in the described preferred embodiments the waveguide comprises a core and a cladding, and wherein part of the semitransparent mirror(s) is formed within the cladding.

According to still further features in the described preferred embodiments the semitransparent mirror(s) is slanted with respect to the waveguide.

According to still further features in the described preferred embodiments the semitransparent mirror(s) is planar.

According to still further features in the described preferred embodiments the semitransparent mirror(s) is curved.

According to still further features in the described preferred embodiments the semitransparent mirror(s) comprises a plurality of semitransparent mirrors distributed along the waveguide so as to provide optical output having a predetermined profile.

According to still further features in the described preferred embodiments the semitransparent mirror(s) comprises a plurality of semitransparent mirrors and wherein at least two of the plurality of semitransparent mirrors are characterized by different refractive indices selected so as to provide optical output having a predetermined profile.

According to still further features in the described preferred embodiments the predetermined profile is a generally uniform intensity profile.

According to yet an additional aspect of the present invention there is provided a method of fabricating an optical device. The method comprises: (a) depositing a core layer on a cladding layer; (b) forming at least one semitransparent mirror structure in the cladding layer; and (c) depositing a cladding layer on the core layer.

According to still further features in the described preferred embodiments the method further comprising prior to the step (c): processing the core layer to form a plurality of recesses in the core layer; and filling the plurality of recesses with a cladding material.

According to still further features in the described preferred embodiments step (b) is effected by exposing the core layer to focused UV radiation.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. In case of conflict, the patent specification, including definitions, will control. In addition, the materials, methods, and examples are illustrative only and not intended to be limiting.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIGS. 1a-d are schematic illustrations of various techniques for light tapping;

FIG. 2a is schematic illustration of an optical device, according to various exemplary embodiments of the present invention;

FIG. 2b is a schematic illustration of the propagation of light having a fundamental mode and a first order mode in a waveguide having a small perturbation therein;

FIG. 2c is a schematic illustration of the propagation of light having a fundamental mode and a first order mode in a waveguide, according to various exemplary embodiments of the present invention;

FIGS. 3a-d are schematic illustrations of relative position of film material in a waveguide, according to various exemplary embodiments of the present invention;

FIG. 4a is a schematic illustration of a fragmentary view of an optical device having a semitransparent mirror structure where the refractive index of the semitransparent mirror structure has a gradient along the propagation direction of the light, according to various exemplary embodiments of the present invention;

FIG. 4b is a schematic illustration of a fragmentary view of an optical device having a semitransparent mirror structure where the semitransparent mirror structure has a gradually increasing thickness;

FIG. 5 is a schematic illustration of an optical device in an embodiment in which the device comprises a series of semitransparent mirror structures;

FIG. 6 is a schematic illustration of a fragmentary view of an optical device having a semitransparent mirror structure where the mirror structure is formed of two films, according to various exemplary embodiments of the present invention;

FIG. 7 is schematic illustrations of an optical device having a semitransparent mirror structure where the orientations of adjacent semitransparent mirror structures differ, according to various exemplary embodiments of the present invention;

FIGS. 8a-d are schematic illustrations of an optical device which comprises semitransparent mirror structures having a curvature (FIG. 8a-b) and the shape of polyhedron (FIG. 8c-d), according to various exemplary embodiments of the present invention;

FIGS. 9a-b are schematic illustrations of an optical device having a waveguide and semitransparent mirror structures, where spacing between the semitransparent mirror structures varies along the waveguide, according to various exemplary embodiments of the present invention;

FIGS. 9c-d are schematic illustrations of an optical device having a waveguide and semitransparent mirror structures, where different individual semitransparent mirror structures have different reflectivity, according to various exemplary embodiments of the present invention;

FIGS. 9e-f are schematic illustrations of an optical device having a waveguide, semitransparent mirror structures and a reflective layer which is characterized by a non uniform reflectivity along the waveguide, according to various exemplary embodiments of the present invention;

FIG. 10 is a schematic illustration of an optical device configured to receive light from both ends, according to various exemplary embodiments of the present invention;

FIG. 11 is a schematic illustration of a display apparatus, according to various exemplary embodiments of the present invention;

FIG. 12a is a schematic illustration of a backlight assembly which provides RGB illumination, according to various exemplary embodiments of the present invention;

FIG. 12b is a schematic illustration of a cross sectional view of FIG. 12a along the line A-A′ and the associated display's pixels;

FIG. 13 is a schematic illustration of an interferometer device, according to various exemplary embodiments of the present invention;

FIGS. 14a-b are schematic illustrations of a surface emitting laser device, according to various exemplary embodiments of the present invention;

FIGS. 15a-b are schematic illustrations of a side view (FIG. 15a) and a top view (FIG. 15b) of a light emitting device, according to various exemplary embodiments of the present invention;

FIG. 16 is a flowchart diagram of a method suitable for fabricating an optical device according to various exemplary embodiments of the present invention

FIGS. 17a-24b are schematic process illustrations for fabrication processes of an optical device, in accordance with some embodiments of the present invention;

FIGS. 25a-b are schematic process illustrations of a structure having varying refractive index, according to various exemplary embodiments of the present invention;

FIGS. 26a-d are schematic process illustration which exemplify a technique for manufacturing a plurality of waveguide embedded in a substrate, according to various exemplary embodiments of the present invention; and

FIGS. 27a-32c show simulation results performed according to various exemplary embodiments of the present invention.

### DESCRIPTION OF EXEMPLARY EMBODIMENTS

The present embodiments comprise an optical device and a method for manufacturing an optical device. Some embodiments of the present invention can be used to couple out light propagating in a waveguide's core (even if the light penetration to the cladding is minimal) and can be employed in many applications, including, without limitation, light taping, light splitting (e.g., bus type), light spreading, backlighting and the like. Some embodiments of the present invention can be used for generating light and emitting the light through a surface.

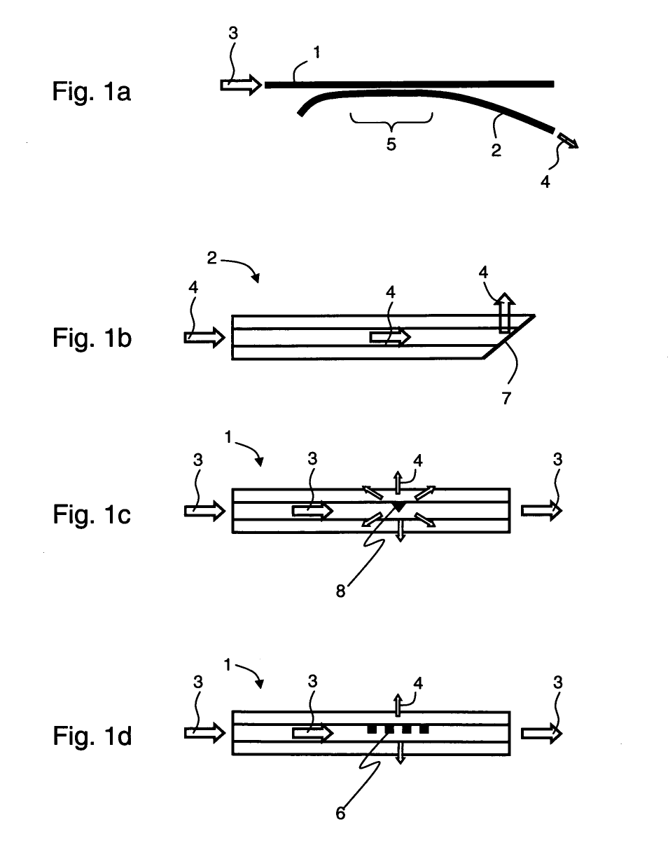

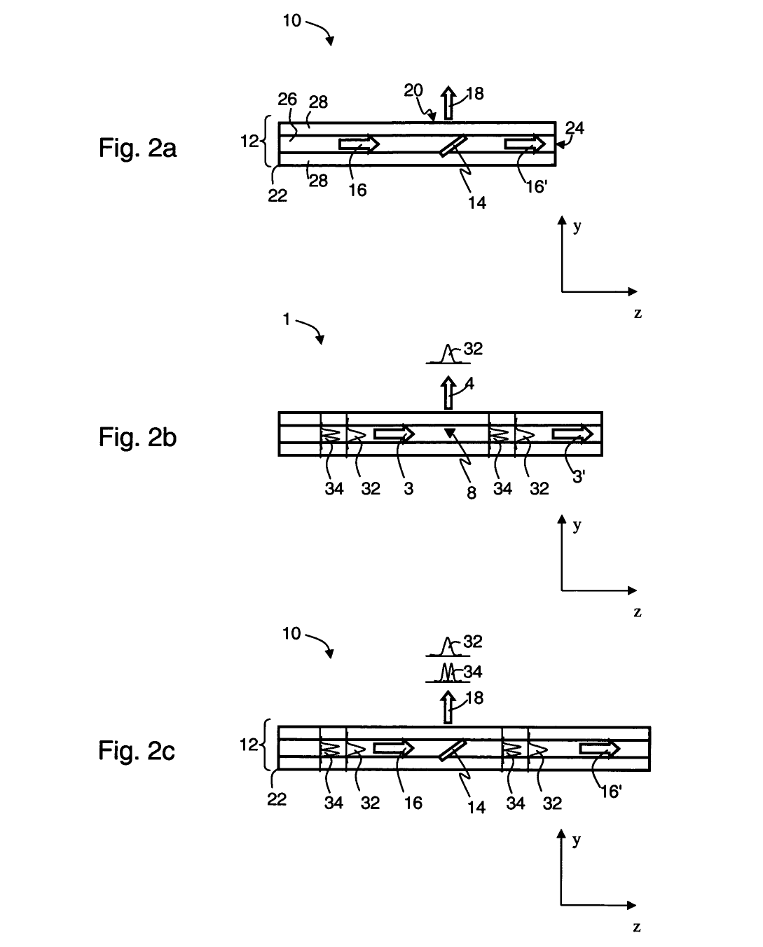

For purposes of better understanding the exemplary embodiments illustrated in FIGS. 2-32 of the drawings, reference is first made to conventional light tapping techniques as illustrated in FIGS. 1a-d.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

FIG. 1a is a schematic illustration of a top view of two optical waveguides 1 and 2, arranged such that there is a region 5 in which the waveguides are in close proximity to each other. Light 3 enters waveguide 1 and propagate therein. Region 5 serves as a coupling region between the waveguides. The evanescent waves of light 3 are coupled into waveguide 2 and propagate therein; thus light tapping is achieved. However, due to the planar nature of the integrated optic technology it is not possible to couple out this tapped light vertically; for that sake a Total Internal Reflector (TIR) mirror is required. A TIR mirror is schematically illustrated in FIG. 1b.

In FIG. 1b light portion 4 which was coupled into the optical tap via evanescent waves from a main waveguide (not shown, see 1 in FIG. 1a), propagates therein and impinges on mirror 7 which totally reflects the light out of the optical tap. The combination of optical coupler (FIG. 1a) with TIR minor (FIG. 1b) is suitable for integrated optics because the total internal reflection mirror can be positioned such as to redirect the light out of the surface at which the main waveguide and optical tap are embedded. However, the present Inventor has uncovered that oftentimes interferences occur between the main waveguide and the TIR mirror and it is necessary to employ a space consuming configuration in which the TIR mirror is far from the main waveguide.

It was further found by the present Inventors that coupling via evanescent waves is significantly sensitive to the optical mode order. Thus, this technique is particularly inadequate for multi-mode waveguides, because not all the modes can be coupled out at sufficient efficiency or at the same efficiency.

FIG. 1c is a schematic illustration of an additional technique for light tapping. A perturbation 8 is formed in main waveguide 1. Light 3, propagating in waveguide 1 and arriving at perturbation 8, is scattered by perturbation 8 to many directions. Some of the scattering directions do not fulfill the propagation criterion within the waveguide and light rays in these directions are coupled out of the waveguide. The present Inventor realized that this technique has a very low efficiency since not all the light which is coupled out can be collected by a suitable device nor propagates in the waveguide.

FIG. 1d is a schematic illustration of an additional technique for light tapping. Main waveguide 1 is formed with a grating 6 which couples the light out of the waveguide by diffraction. This technique has a much higher efficiency since all the light is coupled out to one direction which is determined by the perturbation period. The present Inventor uncovered that this technique is sensitive to the light wavelength and to the mode order and it requires a relative long grating, making the configuration space consuming. In addition, since the coupling is by evanescent waves, the grating efficiency is reduced when employed in a multi-mode waveguide.

Reference is now made to FIG. 2a, which is a schematic illustration of an optical device 10, according to various exemplary embodiments of the present invention. Device 10 comprises a waveguide 12 and one or more semitransparent mirror structures 14 formed within waveguide 12.

Waveguide 12 is typically suitable for implementation in integrated optics applications, including, without limitation, integrated optical circuits.

Generally, integrated optical circuits are optical circuits having optical functions fabricated or integrated onto/into a substrate, which is typically, but not obligatorily, planar. The substrate used during manufacturing of an integrated optical circuit may be sliced up into individual devices, commonly referred to as “chips”, the optical version of an electronic integrated circuit. As commonly used, the term “integrated optical circuits” includes both monolithic and hybrid circuits. In monolithic circuits, all the components used for the device, such as a source, waveguides and output optical circuitry are integrated on a single substrate. In the case of hybrid circuits, at least one additional component (which may or may not be a chip) are coupled with at least one integrated optical circuit.

Integrated optics has a number of advantages over conventional optical systems composed of discrete elements. These advantages include a reduced loss (since alignment issues are subject to better control), and smaller size, weight, and power consumption. In addition, there is the improved reliability, the reduction of effects caused by vibration, and the possibility of batch fabrication, leading ultimately to reduced cost to the customer.

Thus, according to various exemplary embodiments of the present invention waveguide 12 is embedded within a substrate 22, which is preferably, but not obligatorily planar surface. Waveguide 12 can comprise a core 26 and a cladding 28 which can surround core 26. Unlike an optical fiber which is generally manufactured by pulling a large-diameter structure to form a long thin optical fiber, the waveguide of the present embodiments is typically manufactured by a technique other than pulling. For example, the waveguide of the present embodiments can be embedded in the substrate using a microengineering technique, such as lithography, molding and the like. Representative examples for manufacturing techniques are provided hereinunder.

In various exemplary embodiments of the invention semitransparent mirror structure 14 is designed and constructed to partially reflect light 16 propagating in waveguide 12 (generally along the z direction) such that a portion 18 of light 16 is emitted through a surface 20 of waveguide 12. For example, semitransparent mirror structure 14 can partially reflect the light such that a portion of the light exits through the outer surface of the substrate in which the waveguide is embedded. The other portion of the light (designated 16′) continues to propagate in waveguide 12, and can, for example, exit through an end 24 of the waveguide.

Mirror 14 can be constructed so as to reflect two or more mode of the light with substantially the same reflection efficiency. The term “reflection efficiency” when stated in conjunction to a particular optical mode refers to the ratio between the relative intensity of the particular optical mode in the light which is reflected by the semitransparent mirror structure to the relative intensity of the particular optical mode in the light which impinges the mirror.

The term “substantially the same reflection efficiency” refers to reflection efficiencies characterized by a standard deviation which is less than 20%, more preferably less than 10%, more preferably less than 5%.

When the light is partially reflected from the semitransparent mirror, part of the light may be coupled to undesired, typically higher order, modes. This phenomenon typically occurs wherever the perturbation is presented in the light path. In various exemplary embodiments of the invention mirror 14 is constructed to reduce mixings between optical modes. Preferably, the semitransparent mirror structure is designed and constructed such that coupling to other modes of the light is substantially suppressed. For example, a fundamental mode of the light can interact with mirror 14 substantially without coupling to higher order modes.

The term “suppressed coupling” refer to coupling efficiency characterized by a standard deviation which is less than 10%, more preferably less than 5%, more preferably less than 1%.

The term coupling efficiency refers to the amount of optical power, expressed in percentage, which is transferred from one optical mode to the other. For example, a 10% coupling efficiency of a fundamental mode to a higher order mode describes a process in which 10% of the power of the fundamental mode is transferred to the higher order mode.

The present embodiment is particularly useful when waveguide 12 is a multimode waveguide. In traditional waveguides, such as those having a perturbation for tapping the light (see FIG. 1c, for example), the reflection efficiency is very sensitive to the perturbation location. This is illustrated in FIG. 2b, showing a fundamental mode 32 and a first order mode 34 in waveguide 1. Due to different cross coupling between the modes and the perturbation (the perturbation in FIG. 2b is located at the center of the core), the reflection of first order mode 34 is suppressed and the reflected portion 4 essentially includes only the fundamental mode 32. The propagating portions 3 and 3′ include both fundamental 32 and first order 34 modes.

The present embodiment of the invention is illustrated in FIG. 2c which illustrates the propagation of fundamental mode 32 and first order mode 34 in waveguide 12. As shown portion 18 of the light includes both the first mode and the second mode, preferably at the same intensity.

Configurations in which more than two modes (e.g., three modes or more) are redirected are also contemplated. Thus, unlike traditional perturbation-based techniques in which each mode is reflected with different reflection efficiency, the semitransparent mirror of the present embodiments is capable of partially reflecting two or more optical modes with substantially the same reflection efficiency.

In various exemplary embodiments of the invention the mirror structure are designed and constructed such as to allow emission of light at a predetermined direction from surface 20. In the representative examples shown in FIGS. 2a and 2c, the light is coupled out generally along the y direction.

The minor is preferably made of one or more thin films. The thin film can be either a multi or single dielectric material with a refractive index, n_{film}, which is different from the core refractive index, n_{core}. The film can also be a semi-transparent metal film, or stack of metal films.

Typically, the semitransparent minor structure of the present embodiments occupies the cross section area of core 26 by its entirety since most of the mode is confined in the core. In some embodiments of the present invention minor extends also to the cladding 28, so as to reflect also the part of the mode which is located at the cladding. This is particularly useful for narrow waveguides in which a significant part of the optical mode is also in the cladding. In this case n_{core} is preferably replaced by the effective refractive index n_{eff} which also includes a mode refractive index part that is located in the cladding.

Typically, the light reflected from the semitransparent mirror 14 is a sum of two reflections from both sides of the semitransparent minor facets. In the case of a non coherent light the total reflection is the scalar sum of the two reflections while in the case of a coherent light the total reflection is the vectorial sum of the two reflections. The amount of coherency of the light is given by the coherence length of the light relative to the semitransparent mirror thickness.

For example, the coherence length of a LED is given by:

$${l}_{coh} = \frac{{λ}^{2}}{Δ λ} ,$$

where λ is the wavelength and Δλ is the LED light spectral width. For staying in the non-coherent condition the thickness of the film is preferably larger than the coherence length of the light. For example, a LED characterized by λ of about 0.5 μm and Δλ of about 25 nm, has a coherence length l_{coh} of about 10 μm. Thus, in this example, the thickness of the film is preferably above 10 μm so as to avoid light interface.

When the dielectric film thickness, t_{film}, is larger than the light coherence length, l_{coh} the reflectivity of the semitransparent mirror structure is the scalar sum of the two facet reflections for the transverse electric (TE) and transverse magnetic (TM) polarizations, given by the following equations:

$$\begin{matrix}{R}_{TE} = {[ \frac{{n}_{core} \cdot cos {θ}_{i} - {n}_{film} \cdot cos {θ}_{t}}{{n}_{core} \cdot cos {θ}_{i} + {n}_{film} \cdot cos {θ}_{t}} ]}^{2} & ( EQ . 1 ) \\ {R}_{TM} = {[ \frac{{n}_{film} \cdot cos {θ}_{i} - {n}_{core} \cdot cos {θ}_{t}}{{n}_{film} \cdot cos {θ}_{i} + {n}_{core} \cdot cos {θ}_{t}} ]}^{2} & ( EQ . 2 )\end{matrix}$$

were θᵢ is the angle of the input light (from the core) relative to the slanted film, and θₜ is the angle of propagation in the film. The relation between θᵢ and θₜ is given by Snell's law:

n_{core}·sin θᵢ=n_{film}·sin θₜ. (EQ. 3)

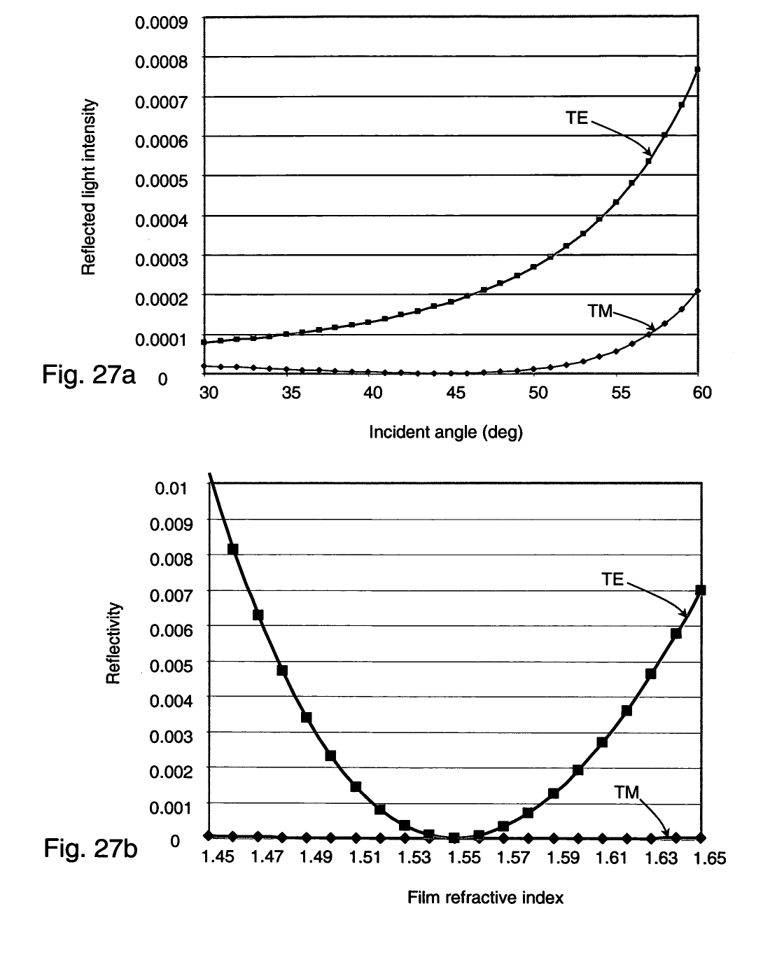

As demonstrated in the Examples section that follows (see FIGS. 27a-b) the semitransparent mirror structure of the present embodiments can provide polarized light. When the propagated light 16 is polarized, the semitransparent mirror structure can maintain its polarization. When the propagated light 16 is not polarized or has more than one polarization component, the semitransparent mirror structure can reflect a polarized light. This embodiment is particularly, but not exclusively, useful for backlighting application is which it is descried to improve the extinction ratio of the display.

The thickness of the dielectric film can also be smaller than the light coherence length. In this embodiment, the two beams interfere and the reflectivity is also a function of the t_{film}. The facet reflection for the TE polarization can be written as:

$${R}_{TE , coherent} = 2 \cdot \frac{{R}_{TE} \cdot [ 1 + cos ( 2 β ) ]}{1 + {R}_{TE} \cdot [ {R}_{TE} + 2 \cdot cos ( 2 β ) ]} \qquad ( EQ . 4 )$$

where

$$β = \frac{2 π}{λ} \cdot {n}_{film} \cdot {t}_{film} \cdot cos {θ}_{film} , λ$$

is the wavelength of the light and θ_{film} is the propagation angle within the film.

When device 10 is designed for guiding a non-coherent light, the typical thickness of the film is from about 500 nm to about 50 μm. When device 10 is designed for guiding a coherent light, the typical thickness of the film is from about 50 nm to about 50 μm.

As used herein the term “about” or “approximately” refers to ±10%.

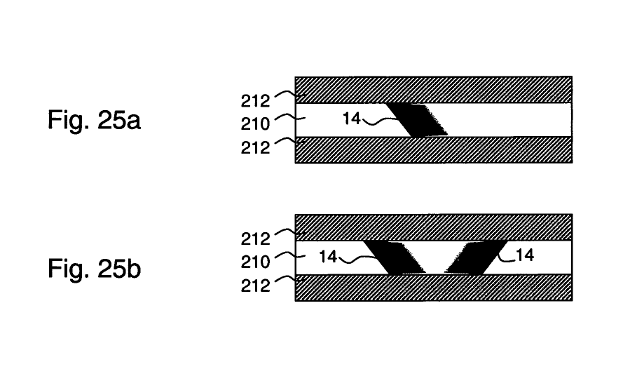

The interference between the two reflected lights can be avoided by removing one of the facets. This can be done by introducing a gradient in the refractive index of semitransparent mirror structure along the propagation direction of the light. A representative implementation of this embodiment is illustrated in FIG. 4a depicting a fragmentary view of device 10. In the present exemplary embodiment, the refractive index n of mirror structure 14 varies along the z direction from a value which is different from n_{core} in one side to a value which is approximately n_{core}, thus forming a refractive index gradient (designated grad(n) in FIG. 4a) along the z direction. A representative example of manufacturing technique for a semitransparent mirror structure having a refractive index gradient is provided hereinunder (see, e.g., FIG. 25 and the accompanying description).

Alternatively, the thickness of the film can vary along the film; in that way the two beams are slightly disorientated and the interference between them is avoided. A representative example is schematically illustrated in FIG. 4b in which the semitransparent mirror structure 14 has a gradually increasing thickness with the smallest thickness near one surface 36 of core 26 and the highest thickness near the opposite surface 38 of core 26.

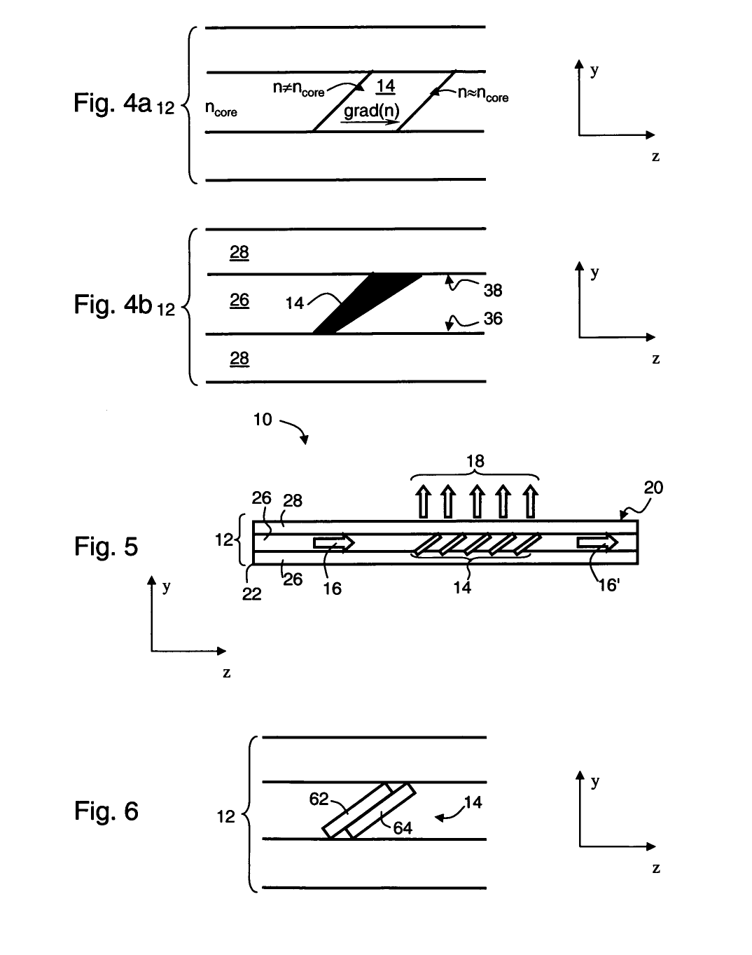

Reference is now made to FIG. 5 which is a schematic illustration of device 10 in an embodiment in which device 10 comprises a series of semitransparent mirror structures 14. According to the present embodiment of the invention, each mirror of the series partially reflects the propagating light 16 such that a portion 18 of the light exits through surface 20 and the remaining portion is transmitted through the mirror and continues to propagate in the waveguide. The semitransparent mirror structures are preferably designed and constructed so as to reduce (e.g., minimize) the distortion of the transmitted portion light. This embodiment is particularly useful when waveguide 12 is a multimode waveguide since in order to control the semitransparent mirrors' reflection efficiency along a waveguide it may be desired to preserve the shape of the light mode along the waveguide. In multi-mode waveguides many modes can be supported. Thus, in various exemplary embodiments of the invention the semitransparent mirror structures of the present embodiments are constructed such that the coupling to other, typically higher order, modes is suppressed. Such configuration ensures low mode distortion while light passes through the semitransparent mirror.

Reduction of optical distortion can be achieved in more than one way. Generally, when device 10 comprises a plurality of semitransparent mirror structures, at least one of the refractive index, thickness, orientation and position of each of the mirror structures can be selected such that the shape of the optical profile along the waveguide is preserved and coupling to other modes is suppressed. The refractive index, thickness, orientation and/or position of each of the mirror structures can alternatively be selected so as to reflect two or more mode of the light with substantially the same reflection efficiency. In various exemplary embodiments of the invention the refractive index, thickness, orientation and/or position of each of the mirror structures is selected such that coupling to other modes is suppressed and two or more mode of the light are reflected with substantially the same reflection efficiency. These embodiments are further detailed hereinbelow.

While the embodiments below are described with a particular emphasis to the configuration in which a plurality of semitransparent mirror structures is employed, it is to be understood that more detailed reference to such configuration is not to be interpreted as limiting the scope of the invention in any way. Specifically, the following description is applicable for an optical device having a single semitransparent mirror structure.

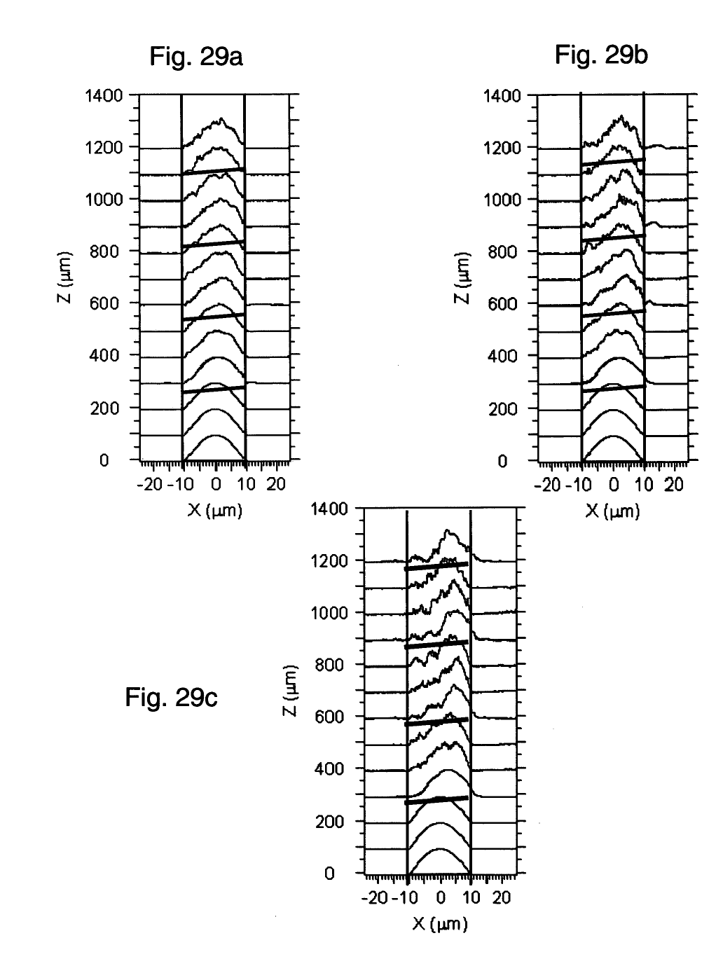

In various exemplary embodiments of the invention the thickness of each semitransparent mirror structure is selected so as to reduce optical distortion. It was found by the Inventor of the present invention (see, e.g., FIGS. 29a-c in the Examples section that follows) that the use of sufficiently thin semitransparent mirror structure can significantly reduce optical distortion. Such significant reduction allows to substantially preserve the shape of the optical profile along the waveguide hence ensures substantially uniform mode distribution along the waveguide.

In various exemplary embodiments of the invention the thickness of the semitransparent mirror structure is less than 20 μm, e.g., about 10 μm or less.

Reduction of optical distortions can also be achieved using more than one film. This embodiment is illustrated in FIG. 6 which is a schematic illustration of a fragmentary view of device 10 showing one of the semitransparent mirror structures. Shown in FIG. 6 is a semitransparent mirror structure 14 having a first film 62 and a second film 64. Films 62 and 64 are preferably aligned adjacently. Film 62 is characterized by a first refractive index n₁, and film 64 is characterized by a second refractive index n₂, where n₁ differ from n₂. Configurations with more than two films are also contemplated.

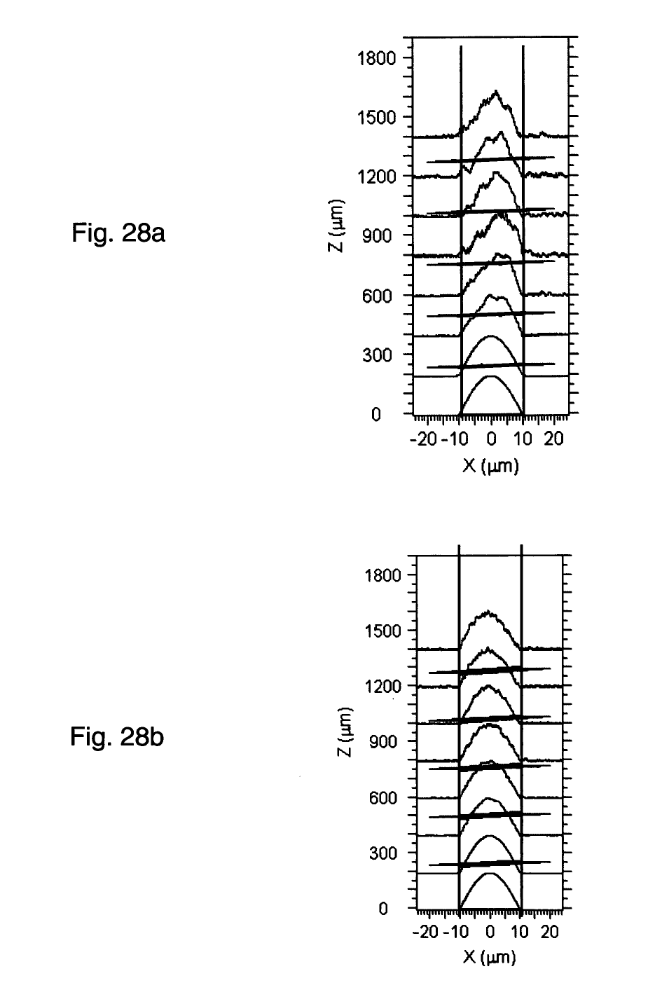

The refractive indices of films 62 and 64 are preferably selected so as to reduce optical distortion. For example, in the case of two films having the same thicknesses, n₁ and n₂ can be selected such that n_{core} is approximately the arithmetic mean of n₁ and n₂. Formally, n_{core}=0.5(n₁+n₂). Thus, according to the present embodiment of the invention the refractive index difference between the films and the core is approximately equal in magnitude but opposite in sign. As demonstrated in the Examples section that follows, (see FIGS. 28a-b), such configuration significantly reduces optical distortions. This reduction allows to substantially preserve the shape of the optical profile along the waveguide hence ensures that there is essential no coupling to (higher order) modes.

The optical distortion is a function of the film thickness and the refractive index difference between the core and the film. Thus, many combinations and subcombinations of refractive indices and thicknesses are contemplated. For example, denoting the refractive index difference between the core and the first film by Δn, and the thicknesses of the first and second film by t_{film,1} and t_{film,2}, the refractive indices and thicknesses can satisfy: n₁=n_{core}+Δn, n₂=n_{core}−2Δn and t_{film,1}=2t_{film,2}

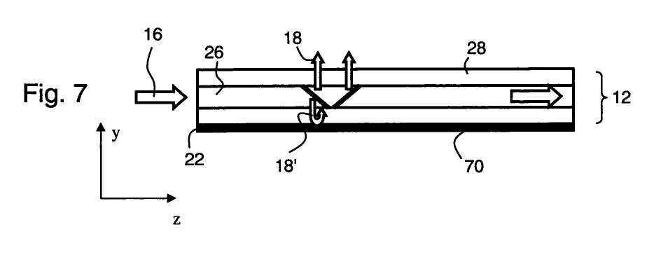

Reduction of optical distortions can also be achieved by judicious selection of the orientation of the semitransparent mirror structures. FIG. 7 is schematic illustrations of device 10 in exemplary embodiments in which the orientations of adjacent semitransparent mirror structures differ. In the representative examples of FIG. 7 the mirrors are slanted such that the orientation angles of two adjacent mirrors with respect to the waveguides is symmetric, i.e., identical angle (and different signs) with the substrate, thus forming producing a V-shape configuration.

The refractive indices and/or thicknesses of two adjacent mirrors can be identical, in which case the adjacent mirrors are preferably arranged to form a V-shape, as described above.

Alternatively two adjacent mirrors can have different refractive indices and/or different thicknesses. In this case, the amount of distortion produced by one mirror is preferably compensated by the adjacent mirror which can be designed to produce the same distortion but to the other direction.

Still alternatively, the orientations of two adjacent semitransparent mirror structures with respect to the waveguide can be asymmetric, in which case the refractive index differences, film thicknesses and/or distance between the two films is preferably tailored so as the distortion produced by one mirror is compensated by the other mirror. When two adjacent mirrors form a V-shape, they are interchangeably referred to herein as a single semitransparent mirror structure whereby the shape of the light profile is preserved after passing through the V-shape structure.

Thus, the present embodiments contemplate any selection of refractive index, thickness, orientation and spacing between mirror structures such that, a set of two adjacent semitransparent mirror structures, or a structure of two or more adjacent semitransparent mirrors, produces mutually canceling optical distortions.

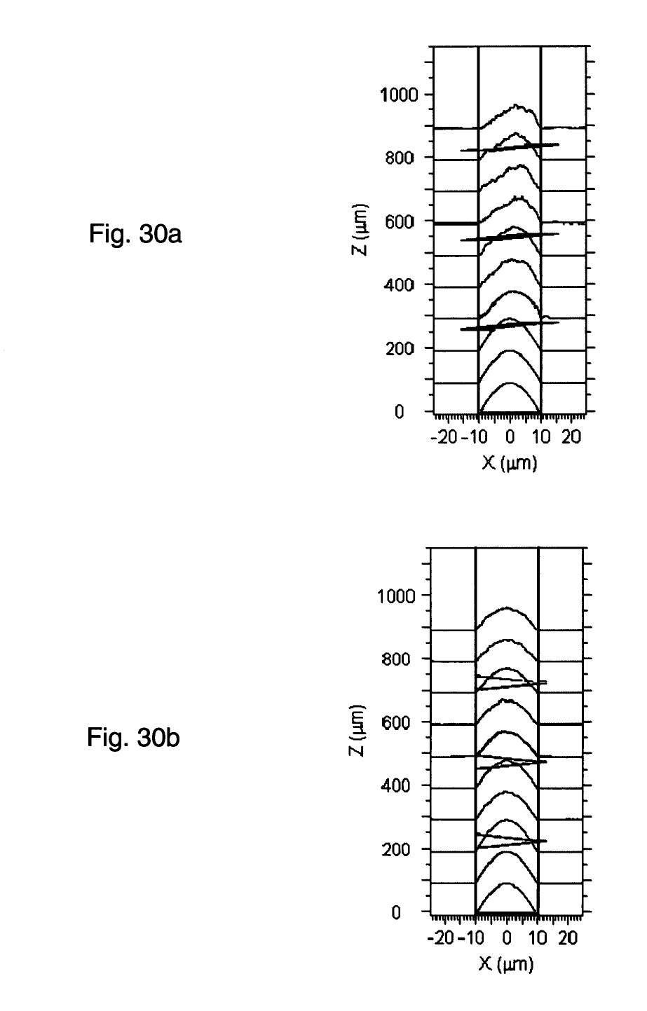

A demonstration of the effect of the adjacent mirror on the beam shape is shown in FIG. 30b in comparison to FIG. 30a. As shown, the shape of the optical profile along the waveguide is substantially preserved.

In the V-shape configuration, device 10 preferably comprises a reflective layer 70. As shown in FIG. 7, due to the existence of two semitransparent mirrors, there are two partially reflected portions of the light. One portion, designated 18′ is reflected to one direction while the other portion, designated 18 is reflected out of waveguide 12. In this embodiment, reflective layer(s) are preferably deposited on substrate 22 such that one of the redirected portions (18′ in the present example) is reflected back and exits waveguide 12 from the same side as the other portion.

Device 10 can be constructed so as to tap the light out of the surface of waveguide 12 in a manner that is suitable to the application for which device 10 is intended.

For example, the shape and orientation of each semitransparent mirror structure can be selected according to the desired shape of the optical output. Thus, in any of the embodiments described above semitransparent mirror structures of the present embodiments can have a planar shape, a polyhedron shape or a curved shape, as desired. Typically, when the semitransparent mirror structure is planar it is slanted with respect to the waveguide, when the semitransparent mirror structure has the shape of polyhedron at least one plane of the polyhedron is slanted with respect to the waveguide, and when the semitransparent mirror structure is curved it is oriented such that at least one slope characterizing the curved surface of the mirror is slanted with respect to the waveguide.

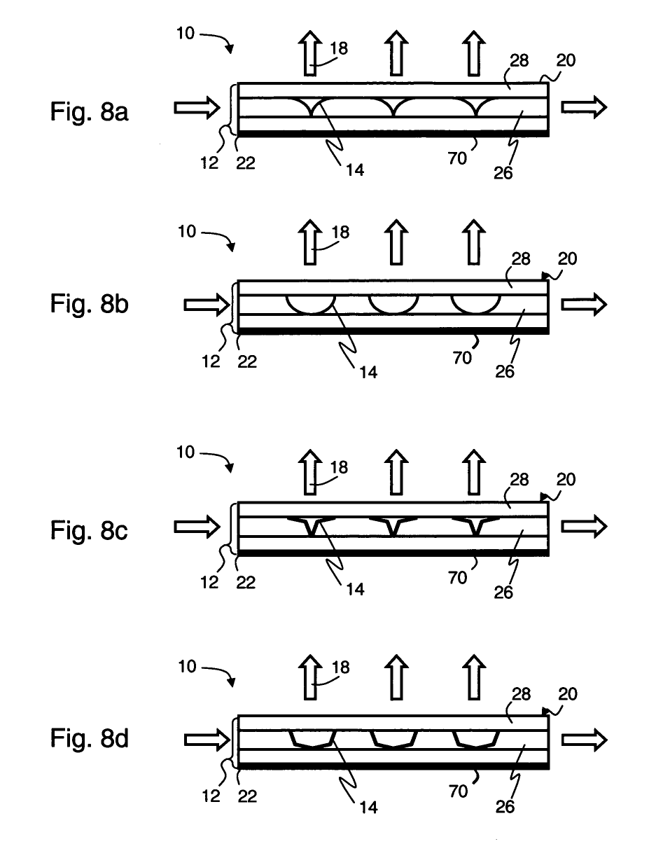

FIGS. 8a-d are schematic illustrations of device 10 in embodiments in which the semitransparent mirror structures have a curvature (FIG. 8a-b) and the shape of polyhedron (FIG. 8c-d).

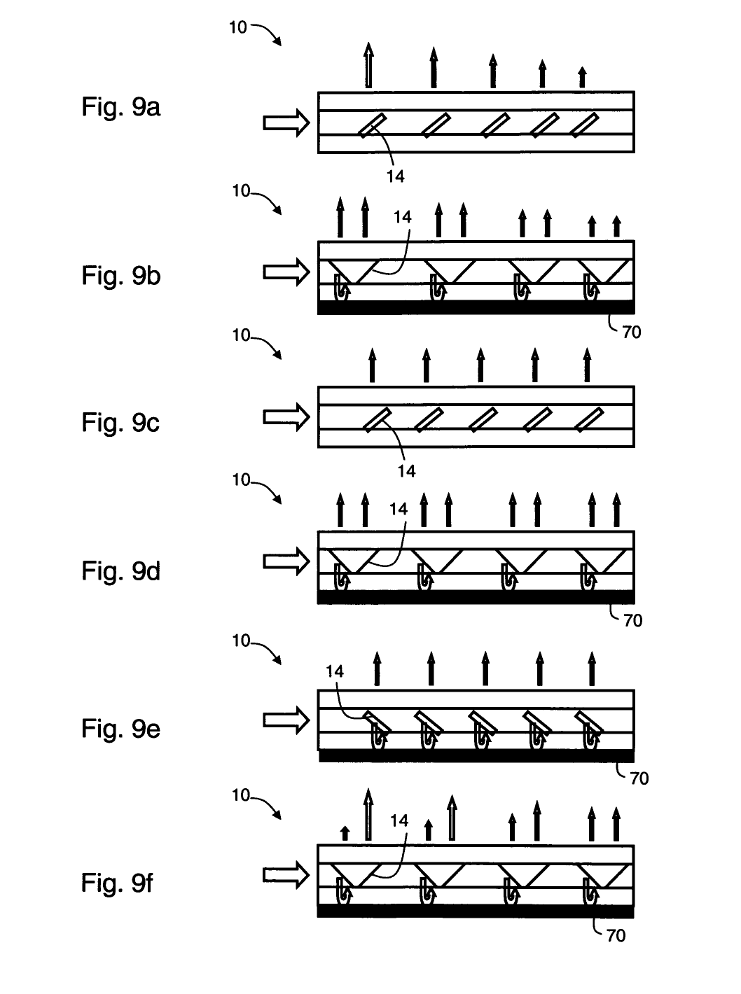

The optical output from the surface of waveguide 12 can also be controlled by judicious selection of the distribution and/or reflectivity of semitransparent mirror structures 14 and/or reflective layers 70. This is can be useful in application in which it is desired to have homogenous reflection intensity along the waveguide. These embodiments are illustrated in FIGS. 9a-f, as follows:

FIGS. 9a-b are schematic illustrations of device 10 in embodiments in which the spacing between the semitransparent mirror structures varies along the waveguide, such that the percentage of tapped light per unit length also varies. In the embodiment illustrated in FIG. 9a the mirrors are parallel to each other and in the embodiment illustrated in FIG. 9b the mirrors are arranged as V-shape structures. FIG. 9b also depicts reflective layer 70 as described above. In various exemplary embodiments of the invention the spaces between the mirrors is gradually decreased such that the percentage of the tapped light per unit length gradually increases. The spaces can be selected so as to provide uniform intensity along the waveguide.

FIGS. 9c-d are schematic illustrations of device 10 in embodiments in which different individual semitransparent mirror structures have different reflectivity. Thus, in this embodiment, the semitransparent mirror structures form a reflectivity gradient along the waveguide. In the embodiment illustrated in FIG. 9c the mirrors are parallel to each other and in the embodiment illustrated in FIG. 9d the mirrors are arranged in V-shape structures and layer 70 is employed. In various exemplary embodiments of the invention the reflectivity of the mirrors is gradually increased such that the percentage of the tapped light per unit length is also gradually increased. The reflectivity gradient can be selected so as to provide uniform intensity along the waveguide.

FIGS. 9e-f are schematic illustrations of device 10 in embodiments in which reflective layer 70 has a non uniform reflectivity along the waveguide. In the embodiment illustrated in FIG. 9e the mirrors are parallel to each other and in the embodiment illustrated in FIG. 9f the mirrors are arranged in V-shape structures. In various exemplary embodiments of the invention the reflectivity of layer 70 gradually increases such that the percentage of the tapped light per unit length is also gradually increased. The reflectivity gradient of layer 70 can be selected so as to provide uniform intensity along the waveguide.

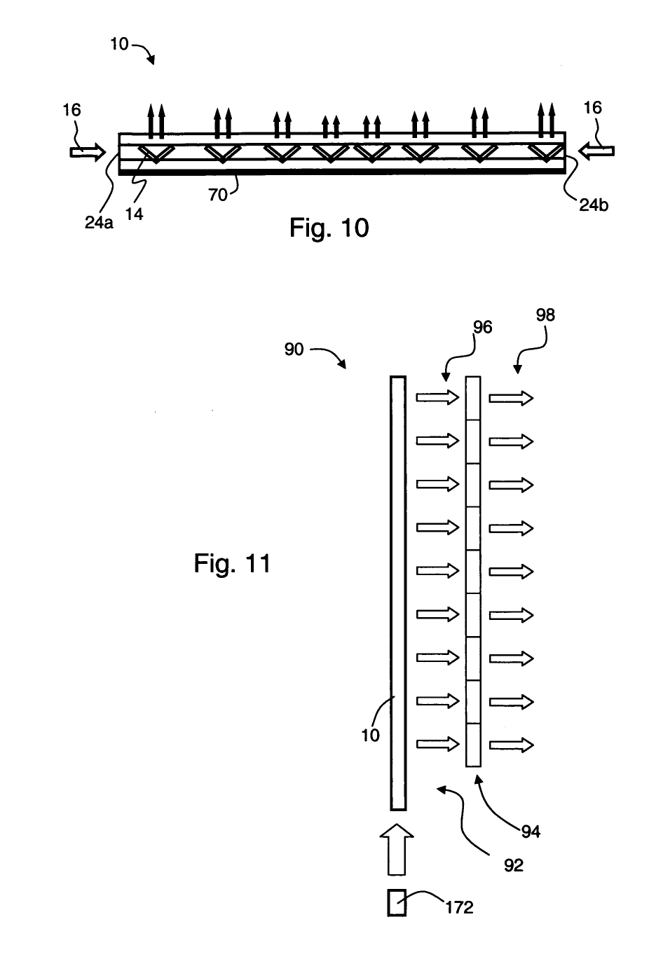

Although device 10 is shown in FIGS. 2-9 as receiving optical input from one end of the device, this need not necessarily be the case, since device 10 can be configured for two way input. A representative example of this embodiment is illustrated in FIG. 10, for the case in which the mirrors are arranged in V-shape structures. As shown, both ends 24a and 24b of the waveguide are adapted for receiving light 16. In this embodiment, the semitransparent mirror structure(s) are designed and constructed to partially reflect both light propagating from end 24a and light propagating from end 24b, with uniform reflection per unit length distribution across the waveguide.

The output profile from the surface of device 10 can be controlled by judicious selection of the distribution and/or reflectivity of the mirrors and/or reflective layer, as further detailed hereinabove.

Following is a description of potential applications offered by the optical device of the present embodiments.

Device 10 can be used, for example, in application in which surface illumination is required. A representative example of such application is a backlight assembly.

FIG. 11 is a schematic illustration of a display apparatus 90 having a backlight assembly 92. The backlight assembly 92 comprises a plurality of optical devices, each being similar in its principles and operation to device 10. Each such device receives light from a light source 172 and transmits illuminating light 96 through its surface to a passive display panel 94, which can be, for example, a liquid crystal panel. When an electric field modulated by imagery data is applied to liquid crystal molecules in panel 94 the optical properties of the liquid crystal are changed and the illuminating light 96 passing through panel 94 is encoded by the imagery data.

Backlight illumination typically requires a uniform output profile. In these embodiments the distribution and/or reflectivity of the mirrors and/or reflective layer (in the embodiments in which such layer is employed) of device 10 is selected to provide uniform intensity across the waveguide, as further detailed hereinabove. Device 10 can be incorporated in a backlight assembly both in one way input in which light enters the device from one end, and in two way input in which light enters from both ends of the device.

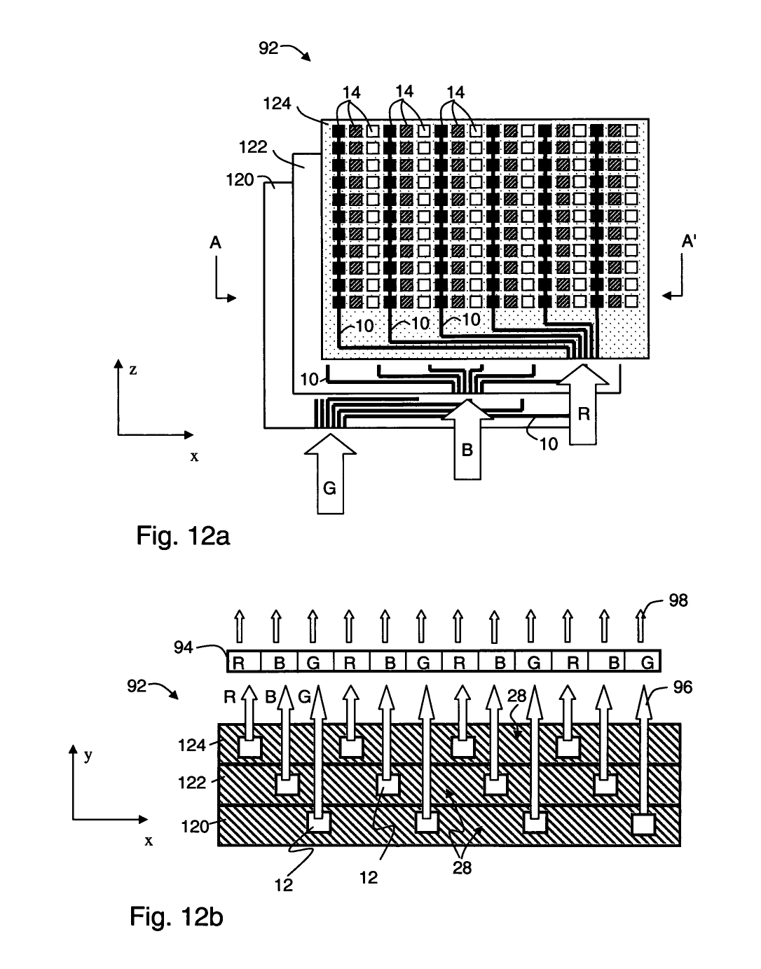

FIG. 12a is a schematic illustration of backlight assembly 92 in an embodiment in which the assembly provides RGB illumination. This embodiment is particularly, but not exclusively, useful for illuminating individual sub-pixel positions of the display panel. More specifically, each optical device 10 can be configured to illuminate one or more sub-pixel positions along a column of the passive display panel.

The backlight assembly 92 shown in FIG. 12a comprises three layers 120, 122 and 124, each having a plurality optical devices 10, where each optical device comprises a waveguide and a plurality of semitransparent mirror structures as further detailed hereinabove. The waveguides are shown in FIG. 12a as thick solid lines and semitransparent mirror structures are shown as squares, where full squares represent mirrors formed within the waveguide embedded in the upper layer (layer 124), patterned squares represent mirrors formed within the waveguide embedded in the middle layer (layer 122), and empty squares represent mirrors formed within the waveguide embedded in the lowest layer (layer 120). For clarity of presentation, lines connecting mirrors in the middle and lowest layers have been omitted from FIG. 12a.

FIG. 12b is a schematic illustration of a cross sectional view of assembly 92 along the line A-A′. As shown, in the present embodiment, each layer is a single substrate in which the waveguides 12 of the layer are embedded. According to various exemplary embodiments of the present invention the waveguides (hence also the semitransparent mirror structures formed therein) are preferably arranged on the layers such that there is a free optical path between the mirrors and passive display panel 94. In other words, there is no spatial overlap between mirrors of different layers. The spacing between adjacent waveguides can be filled with a cladding material 28 or display films such as the LCD back polarizer. The orientations and shapes of the semitransparent mirror structures (not shown in the cross sectional view of FIG. 12b) are preferably selected such that the illuminating light 96 exits each substrate substantially perpendicular to the substrate thereby ensuring that the light successfully penetrates through cladding material 28.

In the present embodiment, each layer is fed with a different color. Specifically, the optical devices arranged on layer 120 are fed with green light, the optical devices arranged on layer 122 are fed with blue light and the optical devices arranged on layer 124 are fed with red light. This configuration allows the colors to be guided separately to their destined column of sub-pixels in panel 94 rather than being mixed to white light.

Device 10 can also be used in application in which it is required to determine phase shifts. A representative example of such application is an interferometer.

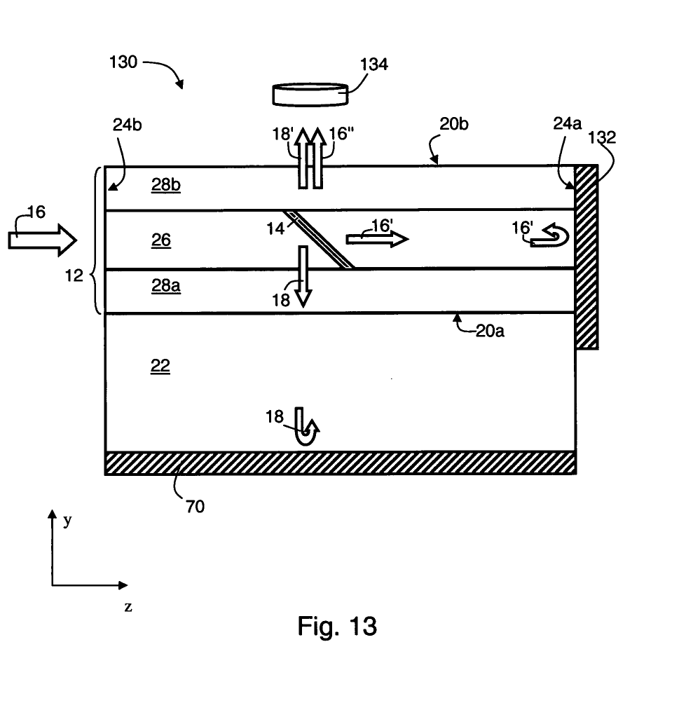

FIG. 13 is a schematic illustration of an interferometer device 130, according to various exemplary embodiments of the present invention. Device 130 can comprise a waveguide 12, an edge mirror 132 terminating a first end 24a of waveguide 12, a surface mirror 70 positioned opposite to a first surface 20a of waveguide 12, and one or more semitransparent mirror structures 14 formed within waveguide 12. Mirrors 14 and waveguide 12 can be similar in their principles and operations to the semitransparent mirror structures and waveguides described above. Mirror 70 is typically parallel to surface 20a of waveguide 12. In various exemplary embodiments of the invention waveguide 12 is formed in a substrate 22. Waveguide 12 can comprise a core 26 and a cladding 28a, 28b surrounding core 26.

In use, light 16 enters waveguide 12 through a second end 24b of waveguide 12 and propagate in waveguide 12 generally along the +z direction. Light 16 is partially reflected in the direction of surface mirror 70 and partially transmitted in the direction of edge mirror 132.

The portion of light which is reflected in the direction of minor 70 is designated in FIG. 13 by reference numeral 18. The direction to which portion 18 is reflected is preferably selected such that portion 18 successfully penetrates cladding 28a and substrate 22 so as to impinge on mirror 70 which reflects it according to the laws of reflection. For example, when portion 18 is reflected approximately perpendicular to surface 20a (the −y direction, in the present example), it is reflected by mirror 70 of waveguide 12 in the opposite direction (the +y direction, in the present example). Mirror 70 is preferably designed to allow generally full reflection (apart for a negligible absorption) of portion 18.

Following the reflection off mirror 70, portion 18 propagates through substrate 22 and cladding 28a to impinge again on mirror structure 14. Being semitransparent, mirror structure 14 allows transmission of light therethrough and a portion 18′ of the light continues to propagate in the +y direction, through cladding 28b and out of a second surface 20b of waveguide 12.

The portion of light 16 which is transmitted through semitransparent mirror structure 14 is designated in FIG. 13 by reference numeral 16′. Similarly to Mirror 70, mirror 132 is preferably designed to allow generally full reflection (apart for a negligible absorption) of portion 16′. Mirror 132 can be aligned such that portion 16′ is reflected generally in the z direction to impinge again on mirror 14, which partially or fully reflect it to form a portion 16″ propagating through cladding 28b out of a second surface 20b of waveguide 12.

Interferometer device 130 can thus serve as a Mach Zehnder Interferometer which splits light 16, to two beams 16″ and 18′. Device 130 can be constructed such that the optical paths traversed by beams 16″ and 18′ differ. Specifically the optical distance between mirrors 14 and 132 is preferably different from the optical distance between mirrors 14 and 70. The two beams 16″ and 18′ can be interfered at a detector 134, as known in the art. The advantage of device 130 over traditional in-plane interferometers is that the path of the two beams can be entirely different, unlike traditional in-plane interferometers in which a change in one arm has some effect on the other arm. For sensing applications, the tested material can be included in substrate 22 or positioned on surface 20b of waveguide 12. In the latter embodiment, the cladding layer 28b is preferably sufficiently thin to allow evanescent waves to be coupled with the tested material.

Device 10 can also be used as a surface emitting light source, for emitting laser or non-coherent radiation.

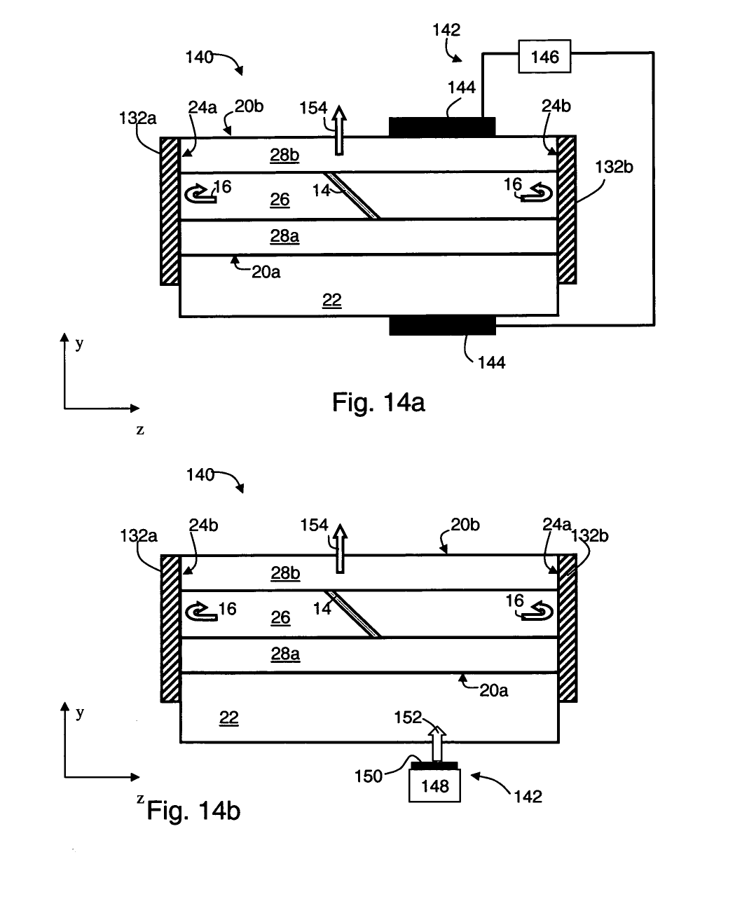

FIGS. 14a-b are schematic illustrations of a surface emitting laser device 140, according to various exemplary embodiments of the present invention. Laser device 140 can comprise a waveguide 12 formed in substrate 22 and having a first end 24a terminated by a first edge mirror 132a and a second end 24b terminated by a second edge mirror 132b. Waveguide 12 can comprise a core 26 and cladding 28a, 28b as described above. Core 26 can serves as the active region of device 140.

Device 140 further comprises a laser pump 142 for inducing light 16 within waveguide 12. Laser pumping can be electrical (FIG. 14a) in which case laser pump 142 comprises a pair of electrical contracts 144 connected to a voltage source 146, or optical (FIG. 14b) in which case laser pump 142 generates pumping radiation 152. For example, pump 142 can comprise a monochromatic light source 148, e.g., a diode array or the like which. Laser pump 142 can also comprise collimating or focusing device 150 for collimating or focusing pumping radiation 152.

In use, laser pump induces light 16 within waveguide 12. Light 16 can be generated across the entire volume of core 26 or at a specific region thereof. Alternatively, light 16 can be generated at the boundary between core 26 and cladding 28a and/or cladding 28b. All these are known to those skilled in the art of laser devices.

Once generated, light 16 passes a plurality of times between edge mirrors 132a and 132b and being at least partially coupled out of surface 20b of waveguide 12 by semitransparent mirror structure(s) 14, to form a laser beam 154. In various exemplary embodiments of the invention edge mirrors 132a and 132b are highly reflective, so as to allow generally full reflection (apart for a negligible absorption) of light 16, and to suppress optical output through ends 24a and 24b. The cross sectional area of laser beam 154 can be controlled by the number and area of the semitransparent mirror structures as further detailed hereinabove. Device 140 can generate laser radiation for many uses, such as, but not limited to, fiber pigtailing.

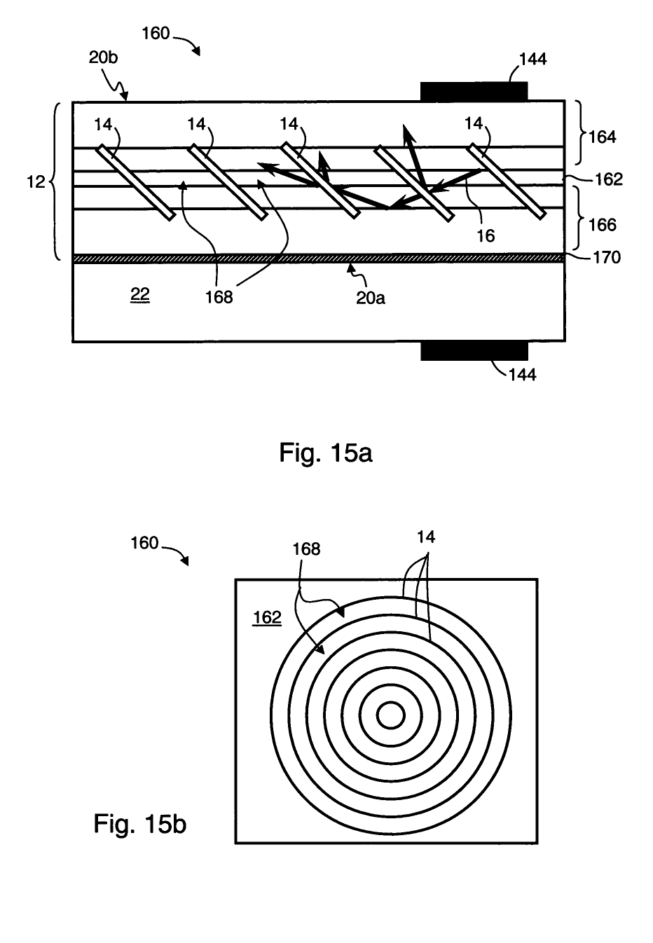

FIGS. 15a-b are schematic illustrations of a side view (FIG. 15a) and a top view (FIG. 15b) of a light emitting device 160, according to various exemplary embodiments of the present invention. Device 160 can comprise a waveguide 12 having therein an active layer 162 for generating light 16, and one or more semitransparent mirror structures 14 formed within active layer 162.

Mirror structures 14 can have a closed shape (e.g., circular shape, see FIG. 15b) such that they define a plurality of closed (e.g., circular) inter-mirror regions 168 within waveguide 12.

Layer 162 can be interposed between one or more p-doped layers 164 and one or more n-doped layers 166. In this embodiment, layer 162 is preferably undoped.

Thus, layers 162, 164 and 166 mimic a light emitting diode. Waveguide 12 can be formed on a substrate 22 as further detailed hereinabove. When substrate 22 is adjacent to a doped layer (one of layers 166 in the present example) it is preferably doped with the same type of impurity as the adjacent layer.

Two electrical contacts 144 are connected to the doped layers of device 160 so as to facilitate application of voltage bias between the p- and n-doped layers.

In use, bias voltage is applied through contacts 144 and light 16 is generated within active layer 162. Light 16 propagate within the various inter-mirror regions 168 of waveguide 12. Upon impinging on a semitransparent mirror structure, one portion of light 16 is reflected off the mirror structure and the other portion is transmitted through the mirror structure to the adjacent inter-mirror region. The distribution, shape, orientation and refractive indices of semitransparent mirror structures 14 is preferably selected to at least partially coupled out light 16 from a surface 20b of waveguide 12.

In various exemplary embodiments of the invention device 160 further comprising a surface mirror 170 positioned opposite to the emitting surface 20 for suppressing optical output through the other surface 20a.

In traditional LED devices, most of the generated light cannot be coupled out of the device due to internal reflection from the LED-air interface. The non-emitted light evanesces within the LED device as is considered optical loss, because the energy used for generating this light is wasted. Unlike conventional LED devices, device 170 comprises semitransparent mirror structures and the generated light experience multiple reflections until it is successfully emitted from the surface of the waveguide. Thus, device 170 is advantageous over traditional LED devices in that a significant portion of the light exits the device without being evanesced.

Following is a description of a method suitable for fabricating an optical device, according to various exemplary embodiments of the present invention. The method can be used, e.g., for fabricating device 10. The method can also be used for fabricating backlight assembly 92, interferometer device 130, surface emitting laser device 140 and light emitting device 160.

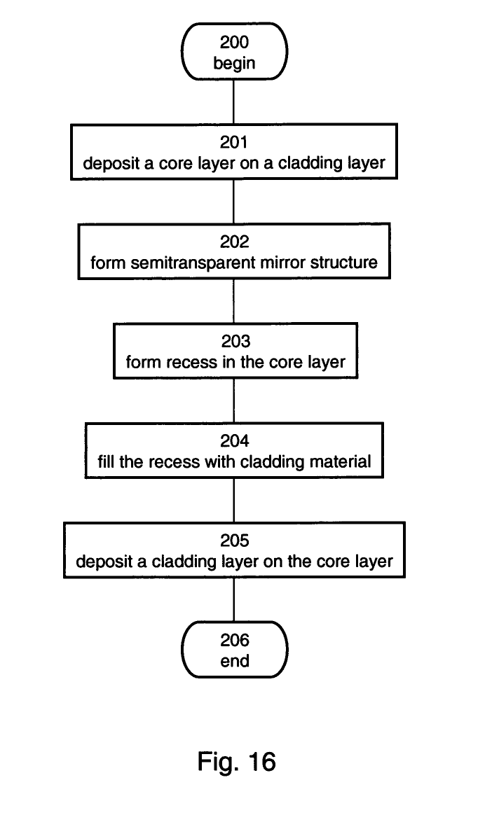

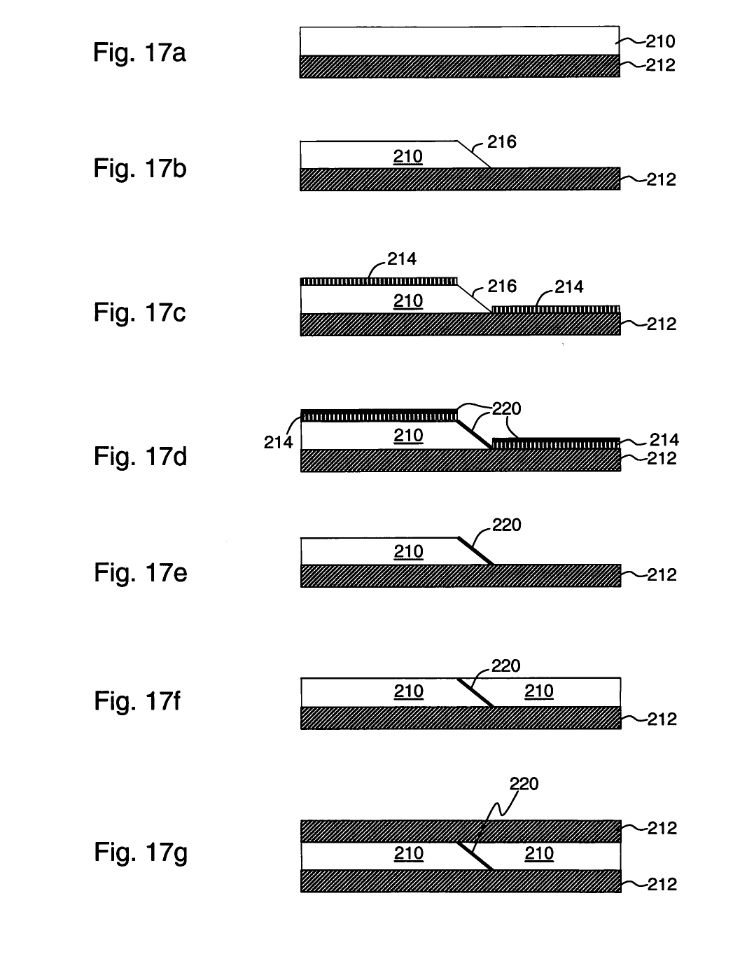

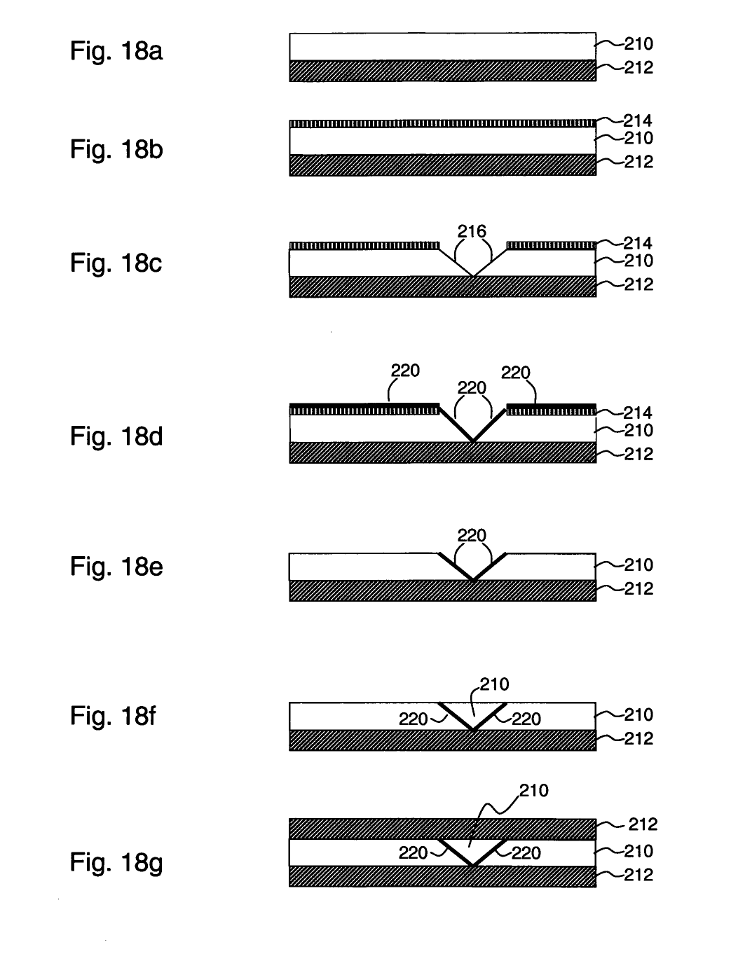

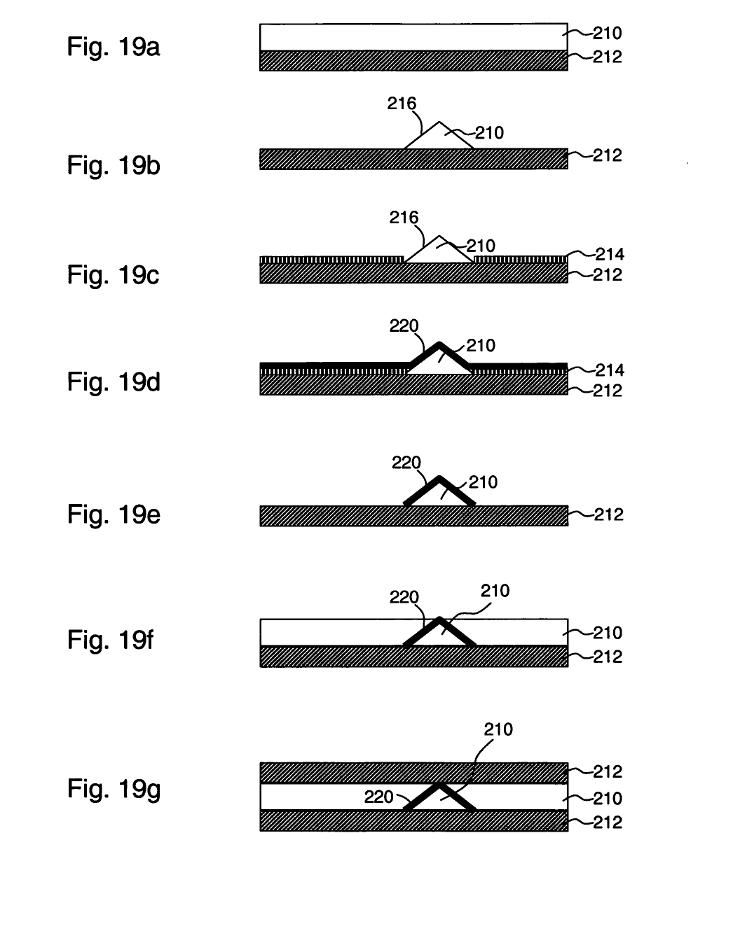

FIG. 16 is a flowchart diagram of the method according to various exemplary embodiments of the present invention. It is to be understood that, unless otherwise defined, the method steps described hereinbelow can be executed either contemporaneously or sequentially in many combinations or orders of execution. Specifically, the ordering of the flowchart diagrams is not to be considered as limiting. For example, two or more method steps, appearing in the following description or in the flowchart diagrams in a particular order, can be executed in a different order (e.g., a reverse order) or substantially contemporaneously. Additionally, several method steps described below are optional and may not be executed.

Generally, the method begins at step 200 and continues to step 201 in which a core layer is deposited on a cladding layer. Any known deposition method can be employed, including, without limitation, material spinning, the so called Dr. Blade method, spraying, sputtering and the like.

The method can then proceed to step 202 in which one or more semitransparent mirror structures is formed in cladding layer. Optionally and preferably, the method continues to step 203 in which a plurality of recesses are formed the core layer, e.g., by lithography followed etching or by a suitable molding technique. Once the recesses are formed, the method can continue to step 204 in which the recesses are filled with a cladding material. The method proceeds to step 205 in which a cladding layer is deposited on the core layer. In the embodiments in which steps 203 and 204 are executed, the cladding layer is deposited on the core layer and the filled recesses. The method ends at step 206.

The method of the present embodiments can be better understood with reference to schematic process illustrations shown in FIGS. 17-24 and 26, which together with the above flowchart diagram illustrate the method of the present embodiments in a non-limiting fashion.

FIGS. 17a-g are process illustrations for fabrication of a waveguide having therein a semitransparent mirror structure, according to various exemplary embodiments of the present invention.

FIG. 17a illustrates deposition of a core layer 210 on a cladding layer 212. Optionally and preferably core layer 210 can be coated by a barrier layer 214 (not shown, see FIG. 17c). Core layer 210 can be made of Optical Polymer (e.g. Ormocore from Microresist) and cladding layer 212 can be made of Optical Polymer with a lower refractive index (e.g. Ormoclad from Microresist). The thickness of layer 210 can be from about 0.5 μm to about 500 μm, and the thickness of layer 212 can be from about 1 μm to about 1000 μm.

FIG. 17b illustrates exposure of a region of cladding layer 212 in a manner such that a slanted facet 216 is formed in core layer 210 and. The process can be executed using any process known in the art, including, without limitation, molding, grooving, etching and the like. The slope of facet 216 can be characterized by any angle from about 10° to about 80°.

FIG. 17c illustrates deposition of a barrier layer 214 on the non slanted region of layer 210 and the exposed region of layer 212.

FIG. 17d illustrates deposition of a thin layer 220 over the slanted facet and the barrier layers. The protective layer serves for preventing coating of the non-slanted regions. Layer 220 serves as a semitransparent mirror structure, and can be made from any multi dielectric material, single dielectric material or semi-transparent metal having a refractive index which is different from the refractive index of layer 210. Also contemplated, is the deposition of a stack of a plurality of layers 220. For example, two layers 220 can be deposited one over the other so as to reduce optical distortions as further detailed hereinabove.

The deposition can be done by any technique known in the art, including, without limitation, sputtering, evaporating, spraying, electrolytic deposition and the like. The thickness of layer 220 can be from about 50 nm to about 50 μm.

FIG. 17e illustrates layers 210, 212 and 220 once barrier layer 214 is removed. The removal of layer 214 can be done using any technique known in the art, including, without limitation, developing.

FIG. 17f illustrates re-deposition of core layer 210 on layer 220 and the exposed region of cladding layer 212, and FIG. 17g illustrates deposition of an additional cladding layer 212 on both parts of core layer 210. In various exemplary embodiments of the invention both cladding layers 212 are made of the same cladding material and both parts of core layer 210 are made of the same core material. The deposition illustrated in FIGS. 17f-g can be done by any of the methods described above.

FIGS. 18a-g are process illustrations for fabrication of a waveguide having therein a plurality of semitransparent minor structures arranged as V-shape structures, according to various exemplary embodiments of the present invention.

FIG. 18a illustrates deposition of a core layer 210 on a cladding layer 212, as further detailed hereinabove.

FIG. 18b illustrates deposition of a barrier layer 214 on core layer 210. Barrier layer 214 serves for masking and can be made from any suitable barrier material, include, without limitation, Photoresist. The deposition of layer 214 can be by any of the deposition methods described above.

FIG. 18c illustrates formation of a V-shape structure 216 in the exposed region of core layer 210. The formation of slanted facts can be done using any process known in the art, including, without limitation, molding, grooving, etching and the like.

FIG. 18d illustrates deposition of a thin layer 220 over the slanted facets and barrier layer 214, as further detailed hereinabove.

FIG. 18e illustrates layers 210, 212 and 220 once barrier layer 214 is removed. As shown, the removal of layer 214 exposes parts of layer 210 because the parts of layer 220 which are not deposited on core 210 are removed with layer 214.

FIG. 18f illustrates deposition of an additional core layer 210 on layer 220, and FIG. 18g illustrates deposition of an additional cladding layer 212 on all parts of core layer 210, as further detailed hereinabove.

FIGS. 19a-g illustrate an alternative process for the fabrication of a waveguide having therein a plurality of semitransparent mirror structures, according to various exemplary embodiments of the present invention. The illustrations in FIGS. 19a-g exemplify fabrication of a waveguide in which the semitransparent mirror structures are arranged as V-shape structures.

FIG. 19a illustrates deposition of a core layer 210 on a cladding layer 212, as further detailed hereinabove.

FIG. 19b illustrates formation of V-shape facets 216 in core layer 210. The formation of the slanted facts can be done using any process known in the art, including, without limitation, molding, grooving, etching and the like. As shown, a portion of core layer 210 is removed, exposing a region on cladding layer 212 while leaving facets 216 protruding above the surface of cladding layer 212.

FIG. 19c illustrated deposition of barrier layer 214 on the exposed parts of cladding layer 212.

FIG. 19d illustrates deposition of a thin layer 220 over the slanted facets and barrier layer 214. The deposition can be using any deposition method known in the art, including, without limitation, spinning. Since the slanted facets form a salient structure (rather than a sunk structure, see e.g., FIG. 18c), the deposition process of layer 220 is simpler.

FIG. 19e illustrates layers 210, 212 and 220 once barrier layer 214 is removed. The removal of layer 214 can be done by any removal technique described above. As shown, the removal of layer 214 exposes parts of layer 212 because the parts of layer 220 which are not deposited on core 210 are removed with layer 214. Thus, the process of removal effects the formation of a salient structure protruding from the surface of layer 212 and comprising a core material 210 coated by film 220.

FIG. 19f illustrates deposition of an additional cladding layer 212 on layer 220 and the exposed parts of layer 212, and FIG. 19g illustrates deposition of an additional cladding layer 212 on all parts of core layer 210, as further detailed hereinabove.

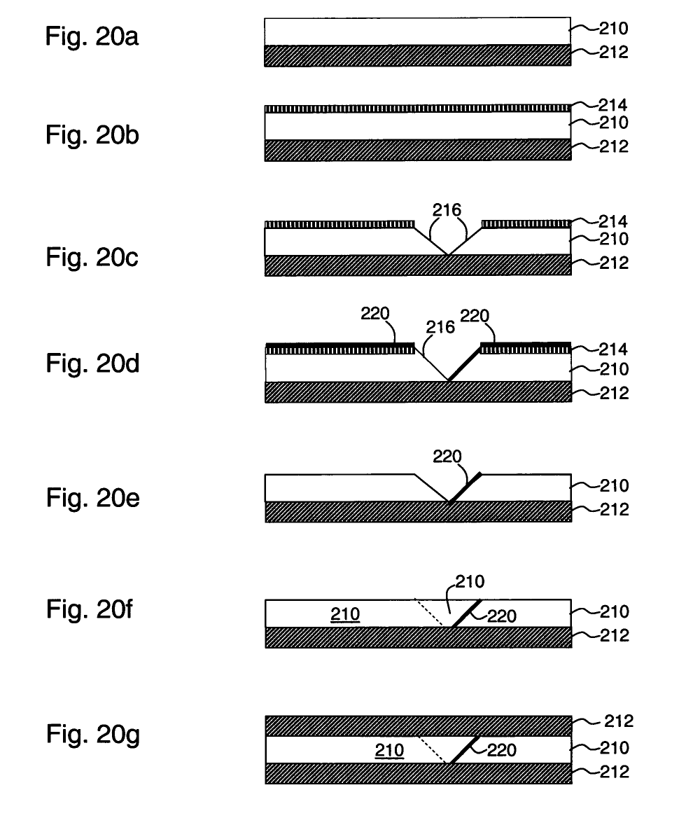

FIGS. 20a-g illustrate a process which is similar to the process illustrated in FIGS. 18a-g, except that the deposition of layer 220 (see FIG. 20d) is done only on one side of the “V” shaped recess. This can be done by tilting the layers with respect to the deposition device (not shown), such that part of the recess is not exposed to the deposition device.

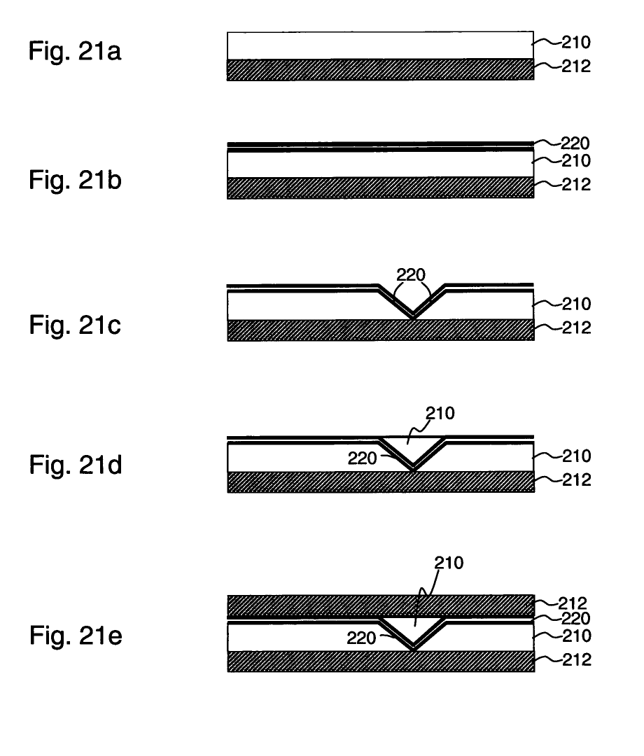

FIGS. 21a-e illustrate a fabrication process in an embodiment of the present invention in which the deposition of layer 220 precedes the formation of the slanted facts.

FIG. 21a illustrates deposition of a core layer 210 on a cladding layer 212, as further detailed hereinabove.

FIG. 21b illustrates deposition of layer 220 on core layer 210. This step can be preceded by partially baking or irradiating (e.g., by UV light) layer 210 such that its exposed surface is sufficiently hardened to allow deposition of a thin film thereon. In the exemplified illustration of FIG. 21b, two layers 220 are deposited one over the other. This embodiment is suitable for forming semitransparent mirror structure having two films for reduction of optical distortions, as further detailed hereinabove.

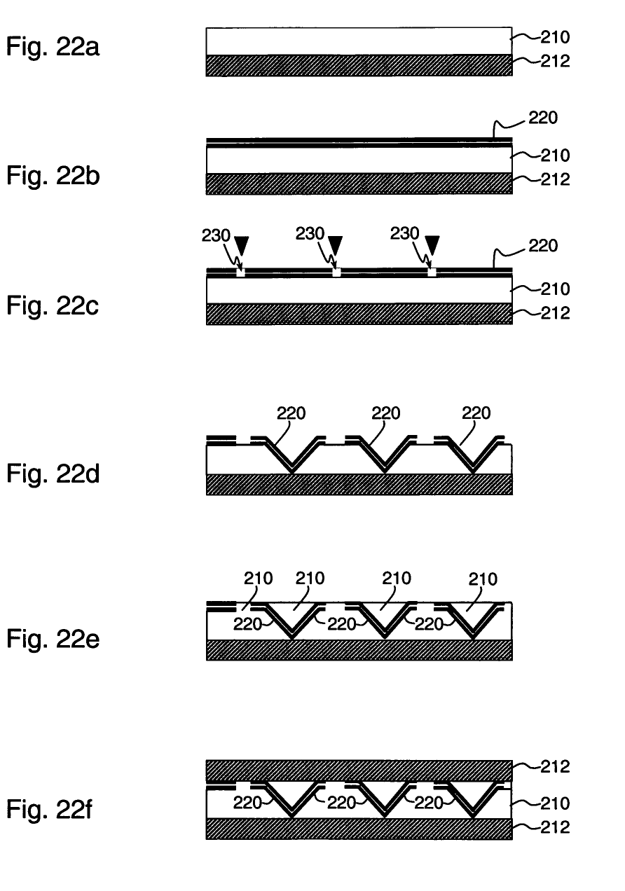

FIG. 21c illustrates a process in which parts of layers 220 are being slanted. In the present illustration, a “V” shape structure is formed, but other shapes are not excluded from the scope of the present invention. The formation of slanted layers can be done by molding core layer 210 together with layers 220. In this way, layers 220 are pressed into core layer 210 and are automatically placed over the slanted facets of core layer 210. Since the surface area is increased during the molding process, the material of layer 220 is preferably sufficiently elastic. Alternatively or additionally, prior to the deposition of layer 220 the surface of layer 210 can be rippled so as to increase the surface area. An additional technique is described hereinunder (see FIGS. 22a-f).

FIG. 21d illustrates deposition of an additional core layer 210 on the slanted parts of layer 220, and FIG. 20e illustrates deposition of an additional cladding layer 212 on the non slanted parts of layers 220 and the exposed parts of core layer 210 and as further detailed hereinabove.

FIGS. 22a-f illustrate a process which is similar to the process illustrated in FIGS. 21a-e, except that prior to the formation of slanted facets, one or more gaps 230 are formed in layer 220 (see FIG. 22c). The formation of slanted facets (FIG. 22d) is performed as described above. The gaps facilitate detachment of one molded region of layer 220 from the other, hence the original surface area of layer 220 is substantially preserved. The process steps illustrated in FIGS. 22e-f are equivalent to the process steps illustrated in FIGS. 21d-e.

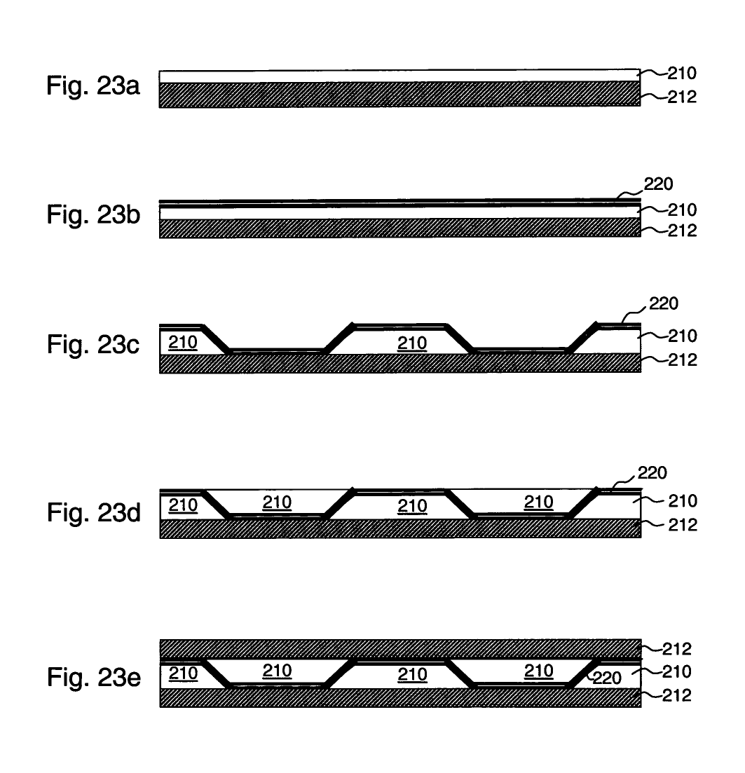

FIGS. 23a-e illustrate a process which is similar to the process illustrated in FIGS. 21a-e, except that the mold used to form the slanted films has the shape of a trapezoid rather than “V” shape. The advantage of the trapezoid shape is that it does not have sharp edges which may cut the polymer during layers deformation. Another advantage is that the overall surface area increase is half the increment of the surface area in the “V” shape mold. The embodiment illustrated FIGS. 23a-e can be combined with the embodiment illustrated in FIGS. 22a-f, by forming gaps in layer 220 prior to the molding step.

In the process steps illustrated in FIGS. 21a-23e, layer 220 is preferably sufficiency thin, e.g., less than 1 μm, and has no affect on the optical properties of the waveguide. Alternatively, the excess film layer which is not above the slanted regions can be removed after step 21c, 22d or 23c by means of etching through a mask.

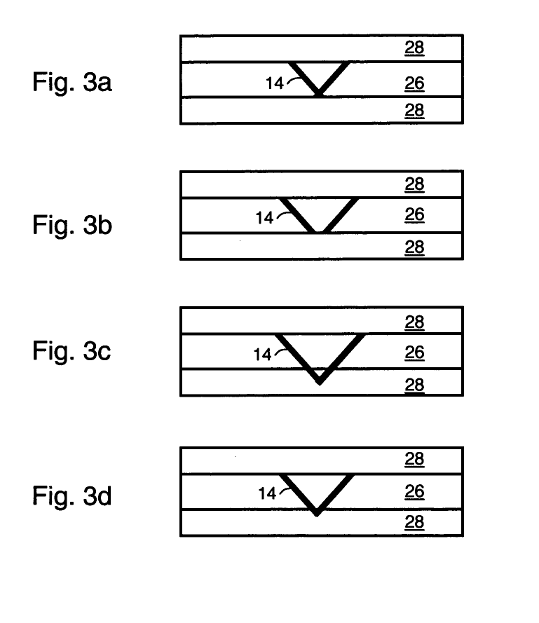

Representative examples for the relative position of the film material in the V-shape configuration are illustrated in FIGS. 3a-d. A device according to any of these exemplified embodiments can be manufactured using the method described above, see, e.g., the process steps illustrated in FIGS. 17a-23e. In FIG. 3a, the semitransparent mirror structures from a “V” shape with an accumulated film material at the core, in FIG. 3b the semitransparent mirror structures form a trapezoid shape, in FIG. 3c there is an accumulated film material at the cladding, and in FIG. 3d there is an accumulated film material immediately beneath the core.

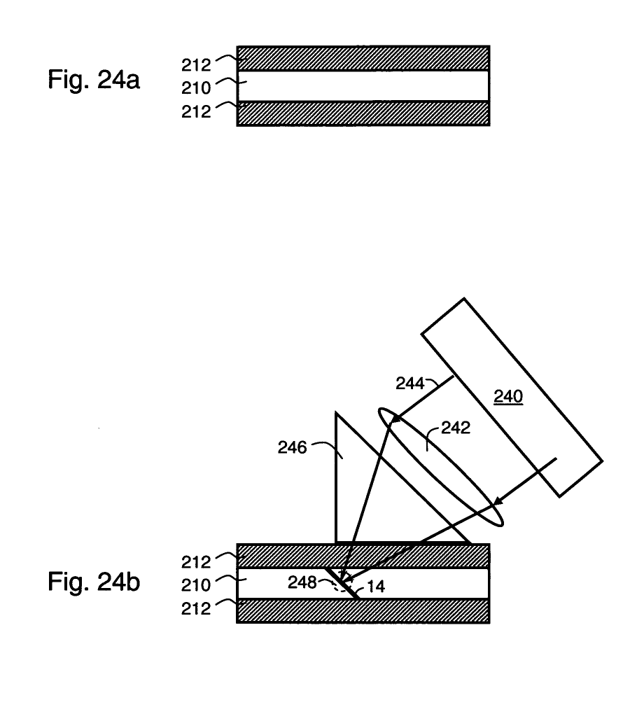

to FIGS. 24a-b illustrates an additional technique for forming the semitransparent mirror structures within the core layer.

FIG. 24a illustrates a core layer 210 interposed between two cladding layers 212. In this embodiment, the core layer is made of a material which is sensitive to UV light by changing its refractive index in locations which are irradiated with focused UV light. The deposition of layers 210 and 212 can be using any of the aforementioned deposition techniques. UV radiation can be applied to a predetermined region within core layer 210 to induce refractive index change hence to form a semitransparent mirror structure at a location within core layer 210 to which UV radiation is focused. The advantage of the present technique is that there is no need to etch or mold and refill the core, thus saving process steps and avoiding potential sidewall roughness.

A representative example of a system for forming the semitransparent mirror structure 14 by UV radiation is illustrated in FIG. 24b. A UV source 240 generates a collimated UV radiation 244 in the direction of a focusing element 242. An index matching prism is positioned between cladding layer 212 and element 242, so as to reduce reflection and/or refraction at the cladding-air interface. Radiation 244 is focused to a location 248 within core layer 210 and induces a refractive index change thereat. Source 240 can be arranged to such that the focused radiation scans and delineate a surface (e.g., slanted plane) within core 210 to thereby induce the refractive index change over the delineated surface. Since the optical characteristics (specifically the refractive index) of the delineated surface differ from the optical characteristics of core 210, semitransparent mirror structure 14 is formed within the core. The scanning process can be repeated one or more times (each scan delineating a different surface) so as to form a plurality of semitransparent mirror structures.

Since the degree of refractive index change depends on the parameters (duration, intensity, density) of the UV radiation, a judicious selection of the irradiation process can control the optical characteristics of the formed semitransparent mirror structure. For example, the UV radiation can be selected so as to form a mirror structure characterized by a refractive index gradient. Representative of such structures is illustrated in FIGS. 25a-b, where the value of refractive index is represented by a gray level (regions of different gray level correspond to regions of different refractive indices).

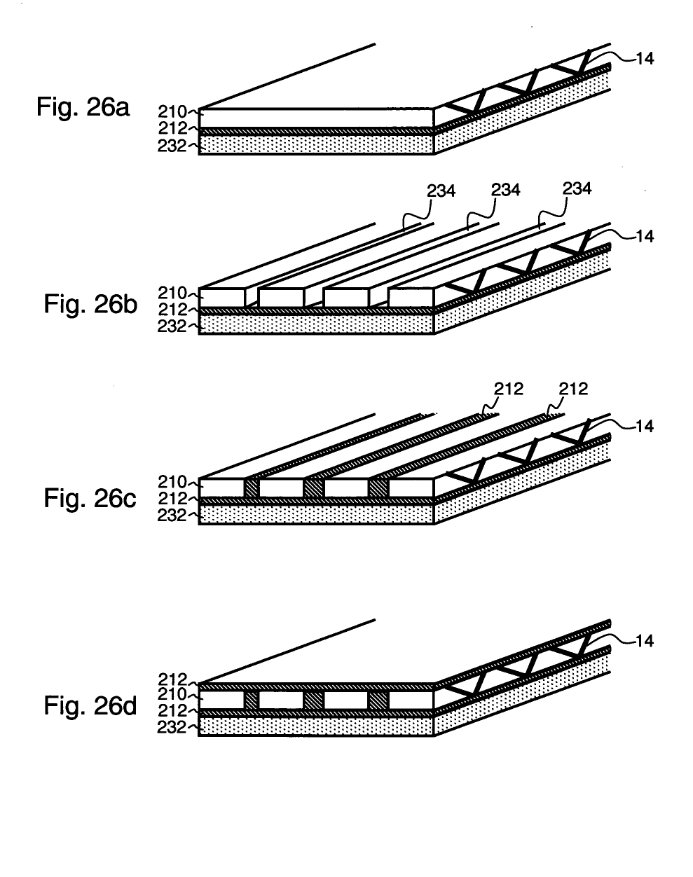

FIGS. 26a-d are schematic process illustration which exemplify a technique for manufacturing a plurality of waveguide embedded in a substrate, according to various exemplary embodiments of the present invention.

FIG. 26a illustrate a substrate 232 having thereon a cladding layer 212 coated by a core layer 210. Layer 210 comprises one or more semitransparent mirror structures 14, which are preferably slanted. The deposition of layers 212 on substrate 232 can be done using any of the aforementioned deposition techniques. The deposition of core layer 210 on cladding layer 212 and formation of the semitransparent mirror structures within layer 210 can be done as described above (see, e.g., FIGS. 17a-f, 18a-f, 19a-f, 20a-f, 21a-d, 22a-e, 23a-d, and 24b without the above cladding layer together with the accompanying descriptions).

FIG. 26b illustrates formation of recesses 234 within core layer 210. The recesses can be formed using any procedure known in the art, such as, but not limited to, lithography followed by etching or molding.

FIG. 26c illustrates deposition of cladding material 212 so as to fill recesses 234, and FIG. 26d illustrates deposition of an additional cladding layer 212 coating the filled recesses and the exposed parts of core layer 210. The deposition can be done using any of the aforementioned deposition techniques.

Additional objects, advantages and novel features of the present invention will become apparent to one ordinarily skilled in the art upon examination of the following examples, which are not intended to be limiting. Additionally, each of the various embodiments and aspects of the present invention as delineated hereinabove and as claimed in the claims section below finds support in the following examples.

### EXAMPLES

Reference is now made to the following examples, which together with the above descriptions illustrate the invention in a non limiting fashion.

### Example 1

In accordance with some embodiments of the present invention, simulations were performed to determine the reflectivity of the semitransparent mirror structure. the reflectivity was calculated both for the TE polarization and the TM polarization.

FIG. 27a shows the reflectivity of plane waves (according to Equations 1 and 2) for n_{core}=1.52 and n_{film}=1.50 as a function of the incident angle, and FIG. 27b shows the reflectivity for n_{core}=1.55 and at incident angle of 45° as a function of the index difference. As shown, the semitransparent mirror structure of the present embodiments is capable of providing polarized light.

### Example 2

In accordance with some embodiments of the present invention, simulations were performed to determine the effect of different refractive indices for adjacent films.

The simulations were performed for a waveguide, 20 μm in width having therein a series of 5 semitransparent mirror structures, positioned at z coordinates of 125 μm, 500 μm, 750 μm, 1000 μm and 1250 μm along the waveguide. Propagation was initiated at z=0. The refractive index of the core was n_{core}=1.50

Two configurations were simulated. In a first configuration, each mirror included a single film of thickness 10 μm, and refractive index of n₁=1.35.

In a second configuration, each mirror included two films (see 62 and 64 in FIG. 6). The thicknesses of the films were 10 μm and their refractive indices were n₁=1.35 and n₂=1.65 thus satisfying n_{core}=0.5(n₁+n₂).

The simulation results are presented in FIGS. 28a (first configuration) and 28b (second configuration). The results are presented in the form of optical profiles of the fundamental mode of the light at different z coordinates. The vertical solid lines in FIGS. 28a-b delineate the boundaries of the simulated core. As demonstrated in FIG. 28b, the use of two films significantly reduces optical distortion.

### Example 3

In accordance with some embodiments of the present invention, simulations were performed to determine the effect of different film thicknesses.

The simulation were performed for a waveguide, 20 μm in width, having a series of 4 semitransparent mirror structures, positioned at z coordinates of 250, 550, 850 and 1150 μm along the waveguide. Propagation was initiated at z=0. The simulations were performed for film thicknesses of 10 μm, 20 μm and 30 μm. The refractive index of the core was n_{core}=1.65 and the refractive index of the mirror was n₁=1.5

The simulation results are shown in FIGS. 29a (film thickness of 10 μm), 29b (film thickness of 20 μm) and 29c (film thickness of 30 μm). The results are presented in the form of optical profiles of the fundamental mode of the light at different z coordinates. The vertical solid lines in FIGS. 29a-c delineate the boundaries of the simulated core. As shown, the use of thinner film thickness (see FIG. 29a for a thickness of 10 μm) significantly reduces optical distortion.

### Example 4

In accordance with some embodiments of the present invention, simulations were performed to determine the effect of a V-shape arrangement of semitransparent mirror structures.

The simulations were performed for waveguides, 20 μm in width. Two configurations were simulated: in a first configuration, the waveguide included a series of 3 parallel semitransparent mirror structures, positioned at z coordinates of 250, 550 and 850 μm along the waveguide. In a second configuration the waveguide included 3 V-shaped structures (each formed of two semitransparent mirror structures), positioned at the same z coordinates as in the first configuration. Propagation was initiated at z=0. The refractive index of the core was n_{core}=1.65 and the refractive index of the mirror was n₁=1.5

The simulation results are shown in FIGS. 30a (first configuration) and 30b (second configuration). The results are presented in the form of optical profiles of the fundamental mode of the light at different z coordinates. The vertical solid lines in FIGS. 30a-b delineate the boundaries of the simulated core. As shown, the use of V shape configuration significantly reduces optical distortion.

### Example 5

In accordance with some embodiments of the present invention, simulations were performed to determine the effect of different film thicknesses.

The simulations were perforated for waveguides, each being 20 μm in width and having a series of semitransparent V-shape mirror structures, The mirrors were located at z coordinates of 200, 450 and 700 μm, and had identical thicknesses and identical refractive indices.

In each simulation of the present example, the refractive index of the core was n_{core}=1.65 and the refractive index of each film was n_{film}=1.5.

Several film thicknesses (10 μm, 20 μm and 30 μm) were simulated. Simulations were performed for the fundamental optical mode as well as for each optical mode of the first three orders.

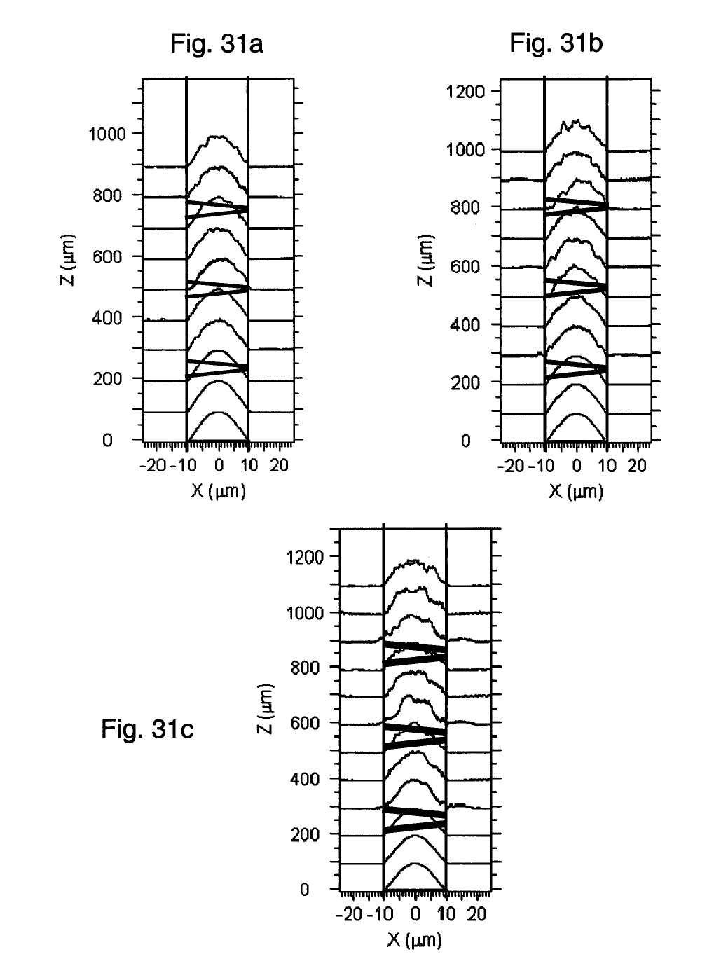

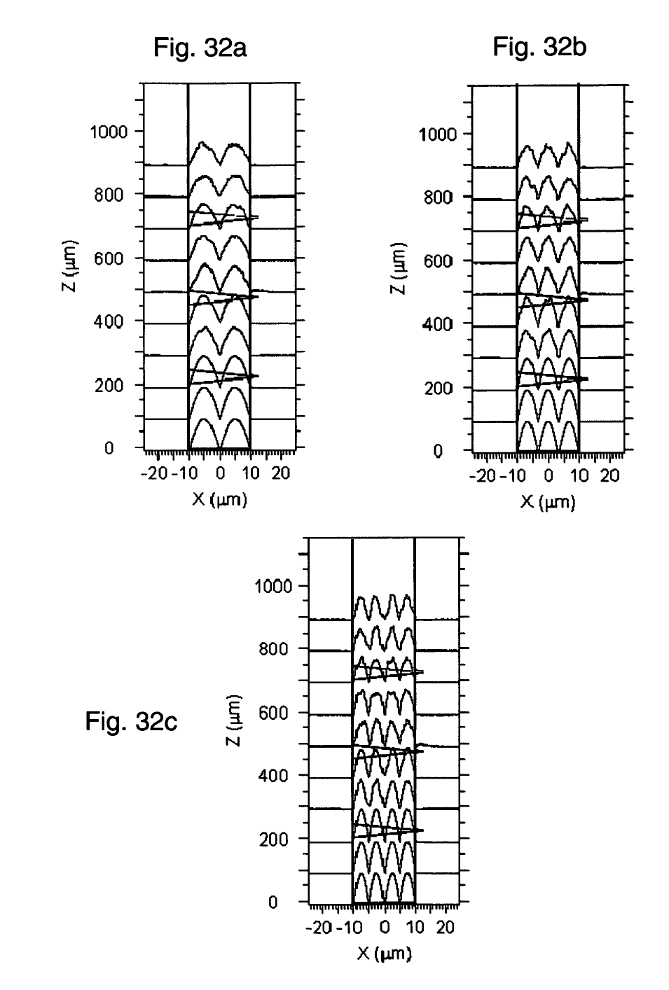

The simulation results are shown in FIGS. 31a-c and 32a-c. The results are presented in the form of optical profiles of the light at different z coordinates. The vertical solid lines in FIGS. 31a-32c delineate the boundaries of the simulated core.

FIGS. 31a-c show simulation results of the fundamental mode for film thicknesses of 10 μm (FIG. 31a), 20 μm (FIG. 31b) and 30 μm (FIG. 31c). Comparing FIGS. 31a-c with FIGS. 29a-c of Example 3, it is demonstrated that the V-shape structure significantly reduces optical distortions, for all film thicknesses. It is further demonstrated that the combination of a sufficiently small thickness (e.g., 10 μm) and V-shape allows preserving the optical profile of the fundamental mode along a propagation distance of about 1 millimeter, within the current example condition.

FIGS. 32a-c show simulation results of the first order mode (FIG. 32a), the second order more (FIG. 32b) and the third order mode (FIG. 32c). In each of the simulations presented in FIGS. 32a-c, the film thickness was 10 μm.

It is demonstrated that the V-shape structure allows to preserve also the optical profile of the first, second and third optical modes.

It was found by the present Inventor that the thickness of the film and the structure of two adjacent compensating mirrors can be selected such that the optical profile is preserved along a propagation distance of a few centimeters.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

1. An optical device, comprising:
a waveguide formed within a substrate and having a surface and at least one end; and
at least one semitransparent mirror structure formed within said waveguide and being designed and constructed to partially reflect light propagating in said waveguide such that a portion of said light is emitted through said surface, said at least one semitransparent mirror being capable of reflecting at least two modes of said light with substantially equal reflection efficiencies.

2. An optical device, comprising:
a waveguide formed within a substrate and having a surface and at least one end; and at least one semitransparent mirror structure formed within said waveguide and being designed and constructed to partially reflect light propagating in said waveguide such that a portion of said light is emitted through said surface, said at least one semitransparent mirror being capable of reflecting at least one optical mode with substantially no power transfer to other modes.

3. The device of claim 1, wherein said substrate comprises at least one reflective layer.

4. The device of claim 1, wherein said at least one end comprising a first end and a second end, wherein each of said first and said second ends is adapted for receiving light, and wherein said at least one semitransparent mirror is designed and constructed to partially reflect both light propagating from said first end and light propagating from said second end.

5. An interferometer device, comprising a waveguide, an edge mirror terminating a first end of said waveguide, a surface mirror positioned opposite to a first surface of said waveguide, and at least one semitransparent mirror structure formed within said waveguide and being designed and constructed such that:
light entering said waveguide through a second end of said waveguide is partially reflected in the direction of said surface mirror and partially transmitted in the direction of said edge mirror; and
light reflected by said surface mirror or said edge mirror is at least partially coupled out of a second surface of said waveguide by said at least one semitransparent mirror structure.

6. A surface emitting laser device, comprising:
a waveguide formed in a substrate and having a first end terminated by a first edge mirror and a second end terminated by a second edge mirror;
a laser pump for inducing light within said waveguide; and
at least one semitransparent mirror structure formed within said waveguide and being designed and constructed such that said light passes a plurality of times between said first and said second edge mirrors and being at least partially coupled out of a surface of said waveguide by said at least one semitransparent mirror structure.

7. A light emitting device, comprising a waveguide having therein an active layer for generating light, and at least one semitransparent mirror structure formed within said active layer and being designed and constructed such that light generated by said active layer is at least partially coupled out of a surface of said waveguide by said at least one semitransparent mirror structure.

8. The device of claim 1, wherein said at least one semitransparent mirror comprises a first film characterized by a first refractive index n₁, and a second film characterized by a second refractive index n₂ being different from said first refractive index.

9. The device of claim 1, wherein said at least one semitransparent mirror comprises a first facet slanted with respect to said waveguide at a first angle, and a second facet slanted with respect to said waveguide at a second angle being different from said first angle.

10. The device of claim 8, wherein said waveguide comprises a core characterized by a refractive index which is approximately the arithmetic mean of said n₁ and said n₂.

11. The device of claim 1, wherein said at least one semitransparent mirror comprises a first film oriented at a first orientation with respect to said waveguide, and a second film oriented at a second orientation with respect to said waveguide, said first orientation being different from said second orientation.

12. The device of claim 11, wherein said first film and said second film are characterized by generally identical refractive indices.

13. The device of claim 11, wherein said first orientation and said second orientation form a V-shape structure, and wherein said substrate comprises at least one reflective layer

14. The device of claim 1, wherein said at least one semitransparent mirror is characterized by a refractive index gradient along a propagation direction of said light within said waveguide.

15. The device of claim 1, wherein a thickness of said semitransparent mirror is selected so as to minimize distortions of all propagation modes in said waveguide.

16. The device of claim 1, wherein said waveguide comprises a core characterized by a cross section area and said at least one semitransparent mirror occupies said cross section area by its entirety.

17. The device of claim 1, wherein said waveguide comprises a core and a cladding, and wherein part of said at least one semitransparent mirror is formed within said cladding.

18. The device of claim 1, wherein said at least one semitransparent mirror is slanted with respect to said waveguide.

19. The device of claim 1, wherein said at least one semitransparent mirror is planar.

20. The device of claim 1, wherein said at least one semitransparent mirror is curved.

21. The device of claim 1, wherein said at least one semitransparent mirror comprises a plurality of semitransparent mirrors distributed along said waveguide so as to provide optical output having a predetermined profile.

22. The device of claim 1, wherein said at least one semitransparent minor comprises a plurality of semitransparent mirrors and wherein at least two of said plurality of semitransparent mirrors are characterized by different refractive indices selected so as to provide optical output having a predetermined profile.

23. The device of claim 21, wherein said predetermined profile is a generally uniform intensity profile.

24. A method of fabricating an optical device, comprising:
(a) depositing a core layer on a cladding layer;
(b) forming at least one semitransparent mirror structure in said cladding layer; and
(c) depositing a cladding layer on said core layer.

25. The method of claim 24, further comprising prior to said step (c):
processing said core layer to form a plurality of recesses in said core layer; and
filling said plurality of recesses with a cladding material.
